(19) United States
(12) Patent Application Publication
(10) Pub. No.: US 2010/0233863 A1
(43) Pub. Date: Sep. 16, 2010

(54) METHOD OF MANUFACTURING SEMICONDUCTOR DEVICE

(75) Inventors: Takeshi Kawamura, Tokyo (JP); Masakazu Okada, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/721,236

(22) Filed: Mar. 10, 2010

(30) Foreign Application Priority Data
Mar. 12, 2009 (JP) 2009-059373

(51) Int. Cl. H01L 21/336

(52) U.S. Cl. 438/287; 438/197; 438/233; 438/687; 257/E21.409; 257/E21.627

(57) ABSTRACT

To provide a technique capable of suppressing the diffusion of copper atoms adhering to the back face of a semiconductor substrate from the back face into the inside of the semiconductor substrate, and capable of suppressing performance degradation of semiconductor elements such as a MISFET formed at the main face of the semiconductor substrate, in semiconductor devices using copper wiring for a wiring layer. A copper diffusion prevention film formed at the main face of the semiconductor substrate is denoted by a first copper diffusion prevention film, and a copper diffusion prevention film formed at the back face of the semiconductor substrate is denoted by a second copper diffusion prevention film. The characteristic of the embodiment lies in that the second copper diffusion prevention film is formed at the back face of the semiconductor substrate. Thus, by the formation of the second copper diffusion prevention film at the back face of the semiconductor substrate prior to the formation of the copper wiring, the diffusion of copper atoms (including copper compounds) from the back face of the semiconductor substrate can be prevented.

### CROSS-REFERENCE TO RELATED APPLICATION

The disclosure of Japanese Patent Application No. 2009-59373 filed on Mar. 12, 2009 including the specification, drawings and abstract is incorporated herein by reference in its entirety.

### BACKGROUND OF THE INVENTION

The present invention relates to a manufacturing technique of a semiconductor device, and, particularly, to a technique that is effective when applied to a manufacturing technique of a semiconductor device using copper wiring.

Japanese Patent Application Laid-Open No. 2000-150640 (Patent Document 1) describes a technique for preventing performance degradation of elements caused by a metal contaminant such as copper or a copper compound adhering to the back face of a semiconductor substrate, in a method of manufacturing a semiconductor device including a step of forming a copper-based metal film. Specifically, it describes that a barrier film such as a silicon oxide film is formed at the back face of the semiconductor substrate and, after that, a copper-based metal film is formed at the main face of the semiconductor substrate.

### SUMMARY OF THE INVENTION

Recently, copper having a lower resistance value than aluminum has begun to be used as a wiring material, and, as a technique for forming wiring by processing copper, a wiring formation technique called damascene is examined. The damascene method can broadly be classified into a single-damascene method and a dual-damascene method.

The single-damascene method is a method of forming embedded wiring in a wiring groove, in which, for example, after a wiring groove is formed at an insulating film, a copper film for forming wiring is deposited over the insulating film and inside the wiring groove, and further the copper film is polished by, for example, a chemical mechanical polishing (CMP) method so that it remains only inside the wiring groove.

The dual-damascene method is a method of forming embedded wiring inside a wiring groove and a connection hole, in which after the wiring groove and the connection hole for connecting the wiring groove with the lower layer wiring are formed at an insulating film, a copper film for forming wiring is deposited over the insulating film and inside the wiring groove and connection hole, and further the deposited copper film is polished by CMP so that it remains only inside the wiring groove and connection hole.

By constituting wiring of a semiconductor device from the copper wiring as described above, the resistance reduction of wiring can be realized and the delay of signals transmitted through the wiring can be prevented. In particular, in semiconductor devices using a low-resistance copper wiring, a low-permittivity film having lower permittivity than a silicon oxide film is used for an interlayer insulating film in order to prevent further delay of signals. That is, in order to suppress the delay of signals, since the resistance reduction of wiring and reduction of parasitic capacitance between wirings are useful, the use of copper wiring with low resistance for wiring and the use of a low-permittivity film for an interlayer insulating film are examined.

The copper wiring is formed by the damascene method as described above, and the damascene method uses a CMP method of polishing a copper film. The CMP method is a method of, for example, performing polishing by pressing a semiconductor substrate stuck to a spindle to a polishing pad, while pouring a polishing liquid (slurry) containing silica particles to the surface of the semiconductor substrate (the semiconductor wafer). The CMP method uses both a chemical mechanism of oxidizing the surface of the copper film to be polished with the slurry, and a mechanical mechanism of scraping away mechanically the oxidized layer. That is, the CMP method uses a large amount of slurry being liquid, to force also the back face of the semiconductor substrate to contact the slurry.

The slurry contains a large amount of copper atoms generated by polishing the copper film. Accordingly, a large amount of copper atoms adhere to the back face of the semiconductor substrate that contacts the slurry. The adhered copper atom has such property of easily diffusing in the semiconductor substrate made of silicon. That is, copper has a very large diffusion coefficient in silicon. Therefore, the copper atom adhered to the back face of the semiconductor substrate diffuses in the silicon by, for example, various heat treatments, to arrive at an element region such as a MISFET (Metal Insulator Semiconductor Field Effect Transistor) formed at the surface of the semiconductor substrate. As a result, there are such problems as the degradation of MISFET properties and the increase in leak current.

An object of the present invention is to provide techniques capable of suppressing the diffusion of copper atoms adhering to the back face of a semiconductor substrate from the back face to the inside of the semiconductor substrate, and capable of suppressing the performance degradation of semiconductor elements such as a MISFET formed at the main face of the semiconductor substrate, in semiconductor devices using copper wiring for a wiring layer.

The above and other objects and novel features of the invention will become clear from the description of the specification and accompanying drawings.

Brief explanation of the outline of representative inventions among ones disclosed in the present application is as follows.

A method of manufacturing a semiconductor device according to a representative embodiment includes the steps of: (a) forming a gate insulating film over the main face of a semiconductor substrate; (b) forming a first electroconductive film over the gate insulating film; and (c) patterning the first electroconductive film to form a gate electrode. And, it includes the steps of: (d) forming a source region and a drain region in the semiconductor substrate in alignment with the gate electrode; (e) forming a stressor film for generating strain at a channel-forming region directly under the gate electrode, over the main face of the semiconductor substrate including over the gate electrode, and over the back face of the semiconductor substrate opposite the main face. Further, it includes the steps of: (f) removing both the stressor film formed at the main face of the semiconductor substrate including over the gate electrode and the stressor film formed at the back face of the semiconductor substrate; and (g) after the step (f), forming a first interlayer insulating film that covers the gate electrode over the main face of the semiconductor substrate. Next, it includes the steps of: (h) forming a plug at the first interlayer insulating film; (i) forming a second interlayer insulating film over the first interlayer insulating film at which the plug has been formed; and (j) after the step (i), forming a copper diffusion prevention film for preventing the diffusion of copper into the semiconductor substrate, over the second interlayer insulating film formed over the main face of the semiconductor substrate and over the back face of the semiconductor substrate. Subsequently, it includes the steps of: (k) after the step (j), removing the copper diffusion prevention film formed over the second interlayer insulating film; and (l) after the step (k), forming copper wiring so as to be embedded into the second interlayer insulating film.

Further, a method of manufacturing a semiconductor device according to a representative embodiment includes the steps of: (a) forming a gate insulating film over the main face of a semiconductor substrate; (b) forming a first electroconductive film over the gate insulating film; and (c) patterning the first electroconductive film to form a gate electrode. And, it includes the steps of: (d) forming a source region and a drain region in the semiconductor substrate in alignment with the gate electrode; (e) forming a stressor film for generating strain at a channel-forming region directly under the gate electrode, over the main face of the semiconductor substrate including over the gate electrode, and over the back face of the semiconductor substrate opposite the main face. Further, it is provided with the steps of: (f) removing both the stressor film formed at the main face of the semiconductor substrate including over the gate electrode and the stressor film formed at the back face of the semiconductor substrate; and (g) after the step (f), forming a first interlayer insulating film that covers the gate electrode over the main face of the semiconductor substrate. Next, it includes the steps of: (h) forming a plug at the first interlayer insulating film; (i) forming a second interlayer insulating film over the first interlayer insulating film at which the plug has been formed; and (j) after the step (i), forming a copper diffusion prevention film for preventing the diffusion of copper into the semiconductor substrate, over the second interlayer insulating film formed over the main face of the semiconductor substrate and over the back face of the semiconductor substrate. Subsequently, it includes the steps of: (k) after the step (j), forming a single layer resist film over the copper diffusion prevention film formed over the second interlayer insulating film; (l) after the step (k), patterning the resist film; and (m) after the step (l), patterning the copper diffusion prevention film formed over the second interlayer insulating film using the patterned resist film as a mask. Then, it includes the step of (n) after the step (m), forming copper wiring so as to be embedded into the second interlayer insulating film using the copper diffusion prevention film formed and patterned over the second interlayer insulating film as a mask.

The effect obtained by representative inventions among those disclosed in the application can briefly be explained as follows.

In semiconductor devices using the copper wiring for the wiring layer, it is possible to suppress the diffusion of copper atoms adhering to the back face of the semiconductor substrate from the back face to the inside of the semiconductor substrate. As the result, it is possible to suppress the performance degradation of semiconductor elements such as a MISFET formed at the main face of the semiconductor substrate.

### BRIEF DESCRIPTION OF THE DRAWINGS

FIG. 1 is a cross-sectional view showing a manufacturing process of a semiconductor device in Embodiment 1 of the present invention;

FIG. 2 is a cross-sectional view showing the manufacturing process of the semiconductor device, following FIG. 1;

FIG. 3 is a cross-sectional view showing the manufacturing process of the semiconductor device, following FIG. 2;

FIG. 4 is a cross-sectional view showing the manufacturing process of the semiconductor device, following FIG. 3;

FIG. 5 is a cross-sectional view showing the manufacturing process of the semiconductor device, following FIG. 4;

FIG. 6 is a cross-sectional view showing the manufacturing process of the semiconductor device, following FIG. 5;

FIG. 7 is a cross-sectional view showing the manufacturing process of the semiconductor device, following FIG. 6;

FIG. 8 is a cross-sectional view showing the manufacturing process of the semiconductor device, following FIG. 7;

FIG. 9 is a cross-sectional view showing the manufacturing process of the semiconductor device, following FIG. 8;

FIG. 10 is a cross-sectional view showing the manufacturing process of the semiconductor device, following FIG. 9;

FIG. 11 is a cross-sectional view showing the manufacturing process of the semiconductor device, following FIG. 10;

FIG. 12 is a cross-sectional view showing the manufacturing process of the semiconductor device, following FIG. 11;

FIG. 13 is a cross-sectional view showing the manufacturing process of the semiconductor device, following FIG. 12;

FIG. 14 is a cross-sectional view showing the manufacturing process of the semiconductor device, following FIG. 13;

FIG. 15 is a cross-sectional view showing the manufacturing process of the semiconductor device, following FIG. 14;

FIG. 16 is a cross-sectional view showing the manufacturing process of the semiconductor device, following FIG. 15;

FIG. 17 is a cross-sectional view showing the manufacturing process of the semiconductor device, following FIG. 16;

FIG. 18 is a cross-sectional view showing the manufacturing process of the semiconductor device, following FIG. 17;

FIG. 19 is a cross-sectional view showing the manufacturing process of the semiconductor device, following FIG. 18;

FIG. 20 is a cross-sectional view showing the manufacturing process of the semiconductor device, following FIG. 19;

FIG. 21 is a cross-sectional view showing the manufacturing process of the semiconductor device, following FIG. 20;

FIG. 22 is a cross-sectional view showing the manufacturing process of the semiconductor device, following FIG. 21;

FIG. 23 is a cross-sectional view showing the manufacturing process of the semiconductor device, following FIG. 22;

FIG. 24 is a cross-sectional view showing the manufacturing process of the semiconductor device, following FIG. 23;

FIG. 25 is a cross-sectional view showing the manufacturing process of the semiconductor device, following FIG. 24;

FIG. 26 is a cross-sectional view for explaining problems of a multi-layer resist film;

FIG. 27 is a cross-sectional view for explaining problems of the multi-layer resist film, following FIG. 26;

FIG. 28 is a cross-sectional view for explaining problems of the multi-layer resist film, following FIG. 27;

FIG. 29 is a cross-sectional view showing the manufacturing process of a semiconductor device in Embodiment 2;

FIG. 30 is a cross-sectional view showing the manufacturing process of the semiconductor device, following FIG. 29;

FIG. 31 is a cross-sectional view showing the manufacturing process of the semiconductor device, following FIG. 30;

FIG. 32 is a cross-sectional view showing the manufacturing process of the semiconductor device, following FIG. 31;

FIG. 33 is a cross-sectional view showing the manufacturing process of the semiconductor device, following FIG. 32;

FIG. 34 is a cross-sectional view showing the manufacturing process of the semiconductor device, following FIG. 33;

FIG. 35 is a cross-sectional view showing the manufacturing process of the semiconductor device, following FIG. 34; and

FIG. 36 is a cross-sectional view showing the manufacturing process of the semiconductor device, following FIG. 35.

### DETAILED DESCRIPTION OF THE PREFERRED EMBODIMENTS

The following embodiments will be described, divided into plural sections or embodiments, if necessary for convenience. Except for the case where it shows clearly in particular, they are not mutually unrelated and one has relationships such as a modification, details, and supplementary explanation of some or entire of another.

In the following embodiments, when referring to the number of elements, etc. (including the number, a numeric value, an amount, a range, etc.), they may be not restricted to the specific number but may be greater or smaller than the specific number, except for the case where they are clearly specified in particular and where they are clearly restricted to a specific number theoretically.

Furthermore, in the following embodiments, it is needless to say that an element (including an element step etc.) is not necessarily indispensable, except for the case where it is clearly specified in particular and where it is considered to be clearly indispensable from a theoretical point of view, etc.

Similarly, in the following embodiments, when shape, position relationship, etc. of an element etc. is referred to, what resembles or is similar to the shape substantially shall be included, except for the case where it is clearly specified in particular and where it is considered to be clearly not right from a theoretical point of view. This statement also applies to the numeric value and range described above.

In all the drawings for explaining embodiments, the same symbol is attached to the same member, as a principle, and the repeated explanation thereof is omitted. In order to make a drawing intelligible, hatching may be attached even if it is a plan view.

### Embodiment 1

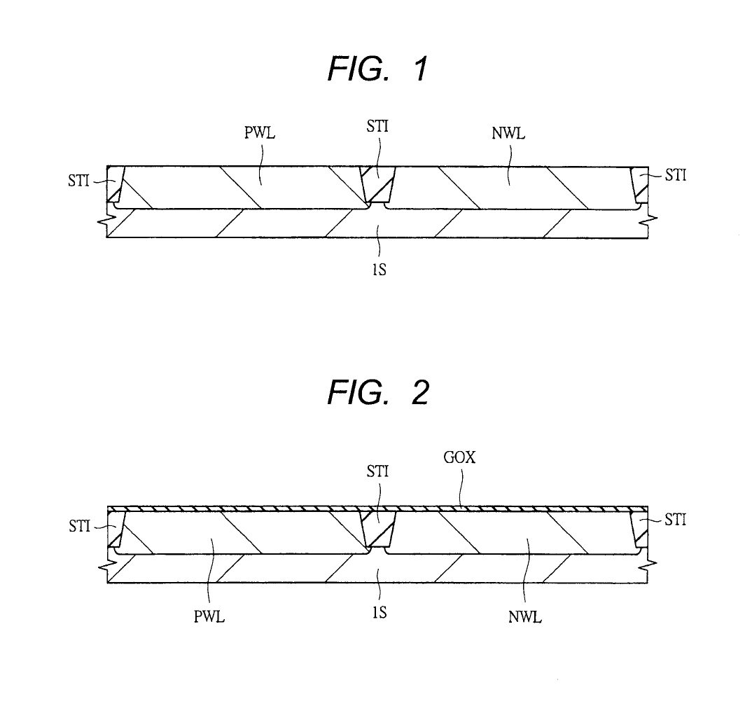

The method of manufacturing a semiconductor device in the present Embodiment 1 will be described while referring to the drawings. Firstly, as shown in FIG. 1, a semiconductor substrate 1S made of a silicon single crystal, into which a p-type impurity such as boron (B) is introduced, is prepared. At this time, the semiconductor substrate 1S is in a state of a semiconductor wafer having an approximately disc-like shape. Then, at a MISFET-forming region of the main face of the semiconductor substrate 1S, an element isolation region STI that isolates between elements is formed. The element isolation region STI is provided so as not to allow elements to interfere with each other. The element isolation region STI can be formed using, for example, a LOCOS (local oxidation of silicon) method or a STI (shallow trench isolation) method. For example, the STI method is used for forming the element isolation region STI as follows. That is, at the semiconductor substrate 1S, an element isolation groove is formed using a photolithographic technique and an etching technique. Then, over the semiconductor substrate, a silicon oxide film is formed so as to be embedded into the element isolation groove, and, after that, an unnecessary silicon oxide film formed over the semiconductor substrate is removed by a chemical mechanical polishing (CMP)method. Consequently, the element isolation region STI, in which a silicon oxide film is embedded only into the element isolation groove, can be formed.

Next, at active regions isolated by the element isolation region STI, an impurity is introduced to form a well. For example, at an n-channel type MISFET-forming region among active regions, a p-type well PWL is formed. The p-type well PWL is formed by, for example, introducing a p-type impurity such as boron into the semiconductor substrate 1S by an ion implantation method. On the other hand, at a p-channel type MISFET-forming region among active regions, an n-type well NWL is formed. The n-type well NWL is formed by, for example, introducing an n-type impurity such as phosphorous or arsenic into the semiconductor substrate 1S by an ion implantation method.

Subsequently, at a surface region of the p-type well PWL, a semiconductor region for forming a channel (not shown) is formed. The semiconductor region for forming a channel is formed in order to regulate the threshold voltage for forming the channel. In the same way, the semiconductor region for forming a channel (not shown) is formed at the surface region of the n-type well NWL. The semiconductor region for forming a channel is formed in order to regulate the threshold voltage for forming the channel.

Next, as shown in FIG. 2, over the semiconductor substrate 1S, a gate insulating film GOX is formed. The gate insulating film GOX is formed from, for example, a silicon oxide film, and can be formed by using, for example, a thermal oxidation method or an ISSG oxidation method. However, the gate insulating film GOX is not limited to a silicon oxide film, which can be changed variously, and, for example, the gate insulating film GOX may be made of a silicon oxynitride (SiON) film. That is, the gate insulating film GOX may have a structure in which nitrogen is introduced therein. The silicon oxynitride film has a higher effect of suppressing the generation of an interface state and of reducing electron traps in the film, as compared with the silicon oxide film. Accordingly, it can improve the hot-carrier resistance and improve the insulation resistance of the gate insulating film GOX. Further, an impurity can hardly pass through the silicon oxynitride film, as compared with the silicon oxide film. Consequently, by using the silicon oxynitride film as the gate insulating film GOX, the variation of the threshold voltage caused by the diffusion of impurities in the gate electrode into the semiconductor substrate 1S side can be suppressed. In order to form the silicon oxynitride film, for example, it is sufficient to subject the semiconductor substrate 1S to a heat treatment in an atmosphere containing nitrogen such as NO, NO₂ or NH₃. Further, the same effect can also be obtained by forming a gate insulating film GOX made of a silicon oxide film at the surface of the semiconductor substrate 1S, then heat-treating the semiconductor substrate 1S in an atmosphere containing nitrogen, and introducing nitrogen into the gate insulating film GOX.

Further, the gate insulating film GOX may be formed from a high-permittivity film, for example, that has a higher permittivity than the silicon oxide film. Conventionally, from the standpoint of high insulation resistance and excellent electric and physical stability at a silicon-silicon oxide interface, the silicon oxide film is used as the gate insulating film GOX. However, along with the miniaturization of elements, a gate insulating film GOX with an extremely thin thickness has been required. When such a thin silicon oxide film is used as the gate insulating film GOX, so-called a tunneling current will be generated, in which electrons flowing through the channel of a MISFET tunnel a barrier formed by the silicon oxide film to flow to the gate electrode.

Therefore, by using a material having a higher permittivity than the silicon oxide film, a high-permittivity film, that can increase the physical film thickness without changing the capacity, has been used. The use of a high-permittivity film can increase the physical film thickness even for the same capacity, and therefore the leak current can be decreased. Particularly, although the silicon nitride film is also a film having a higher permittivity than the silicon oxide film, in Embodiment 1, the use of a film that has a further higher permittivity than that of the silicon nitride film is desirable.

As a high-permittivity film having a higher permittivity than the silicon nitride film, for example, a film of hafnium oxide (an HfO₂ film) that is one of oxides of hafnium may be used. Further, an HfAlO obtained by adding aluminum to the hafnium oxide film may be used. In addition, in place of the hafnium oxide film, other hafnium-based insulating films such as a hafnium aluminate film, an HfON film (a hafnium oxinitride film), an HfSiO film (a hafnium silicate film), an HfSiON film (a hafnium silicon oxinitride film), or an HfAlO film may also be used. Furthermore, hafnium-based insulating films obtained by introducing an oxide such as tantalum oxide, niobium oxide, titanium oxide, zirconium oxide, lanthanum oxide, or yttrium oxide into these hafnium-based insulating films may also be used. Since the hafnium-based insulating film has a higher permittivity than the silicon oxide film and silicon oxynitride film, as is the case for the hafnium oxide film, the use thereof can give the same effect as that given by using the hafnium oxide film.

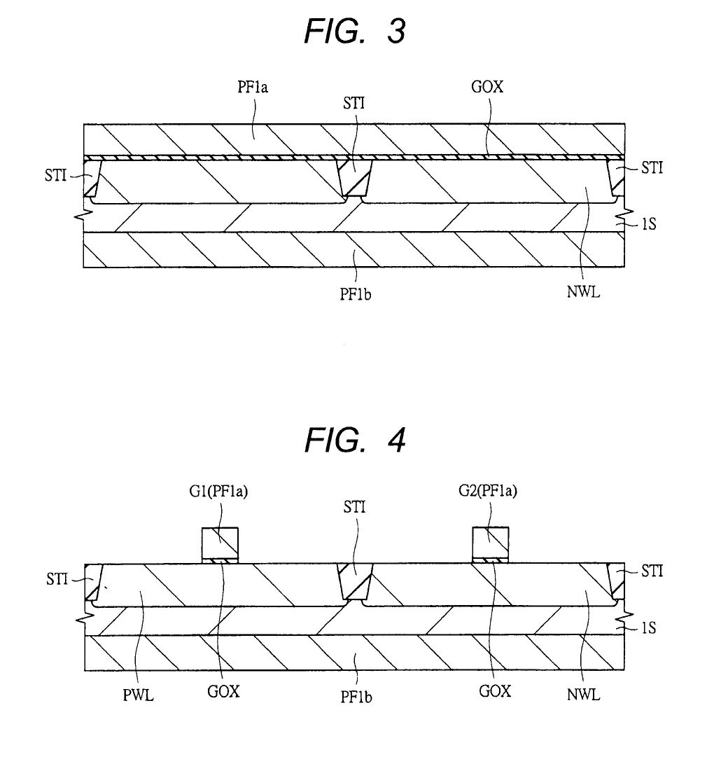

Next, as shown in FIG. 3, a polysilicon film PF1a is formed on the gate insulating film GOX. The polysilicon film PF1a can be formed using, for example, a CVD method. At this time, a polysilicon film PF1b is formed also at the back face of the semiconductor substrate 1S. After that, into the polysilicon film PF1a, an impurity is introduced using a photolithographic technique and an ion implantation method. Specifically, into the polysilicon film PF1a formed at the n-channel type MISFET-forming region, an n-type impurity such as phosphorous or arsenic is introduced, and, into the polysilicon film PF1a formed at the p-channel type MISFET-forming region, a p-type impurity such as boron is introduced.

Subsequently, as shown in FIG. 4, the polysilicon film PF1a is processed by etching using a patterned resist film as a mask to form a gate electrode G1 at the n-channel type MISFET-forming region, and to form a gate electrode G2 at the p-channel type MISFET-forming region.

Here, for the gate electrode G1 of the n-channel type MISFET-forming region, an n-type impurity is introduced into the polysilicon film PF1a. Consequently, the work function value of the gate electrode G1 can be set to a value adjacent to the conduction band of silicon, and therefore the threshold voltage of the n-channel type MISFET can be lowered. On the other hand, for the gate electrode G2 of the p-channel type MISFET-forming region, a p-type impurity is introduced into the polysilicon film PF1a. Consequently, the work function value of the gate electrode G2 can be set to a value adjacent to the valence band of silicon, and therefore the threshold voltage of the p-channel type MISFET can be lowered.

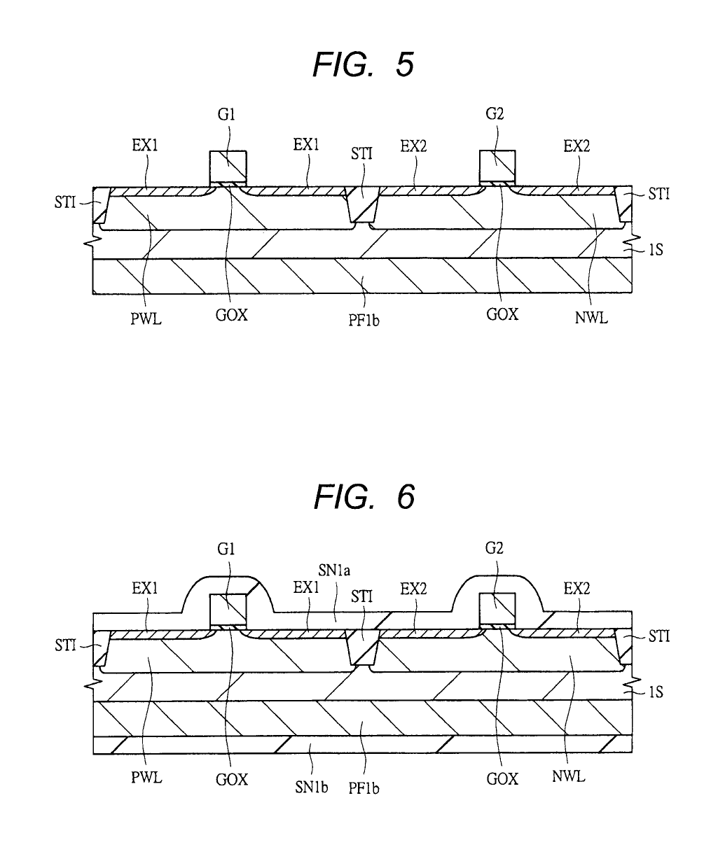

After that, as shown in FIG. 5, a shallow n-type impurity diffusion region EX1 in alignment with the gate electrode G1 of the n-channel type MISFET is formed by using a photolithographic technique and an ion implantation method. The shallow n-type impurity diffusion region EX1 is a semiconductor region. Similarly, a shallow p-type impurity diffusion region EX2 in alignment with the gate electrode G2 of the p-channel type MISFET is formed by using a photolithographic technique and an ion implantation method. The shallow p-type impurity diffusion region EX2 is a semiconductor region, too.

Next, as shown in FIG. 6, a silicon nitride film SN1a is formed over the semiconductor substrate 1S. The silicon nitride film SN1a can be formed, for example, using a CVD method of a batch treatment. At this time, the silicon nitride film SN1a is formed at the main face of the semiconductor substrate 1S, and, at the same time, a silicon nitride film SN1b is also formed at the back face of the semiconductor substrate 1S. As described above, up to processes here, firstly the polysilicon film PF1b is formed on the back face of the semiconductor substrate 1S, and a silicon nitride film SN1 is formed on the polysilicon film PF1b.

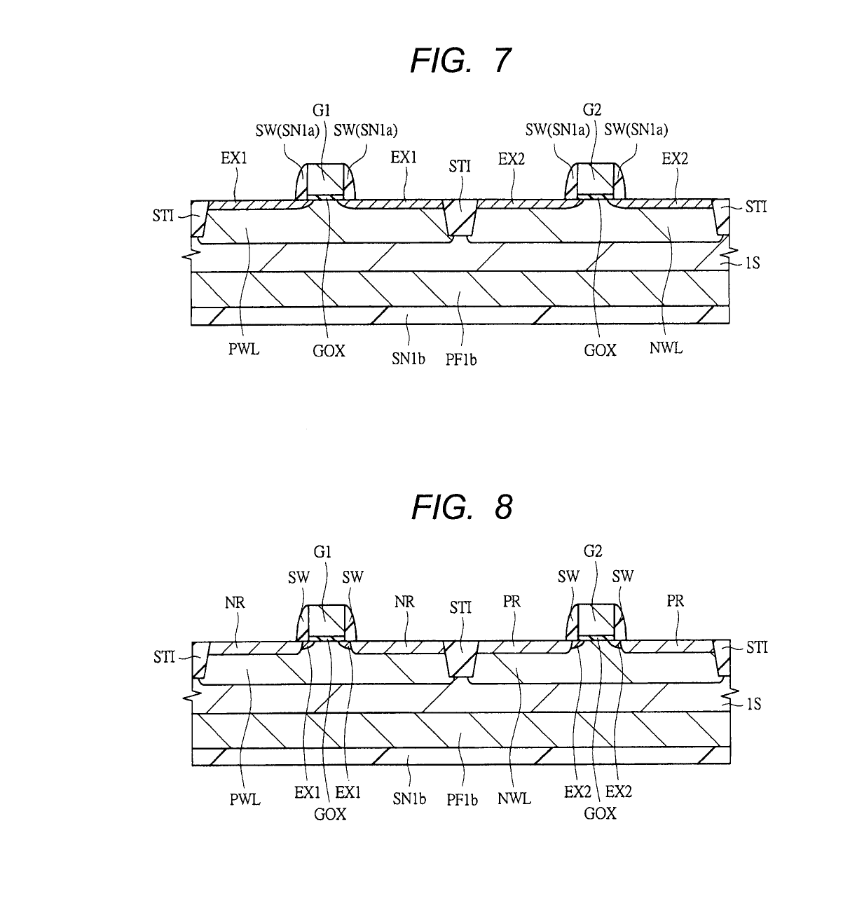

After that, as shown in FIG. 7, the silicon nitride film SN1a formed over the main face of the semiconductor substrate 1S is subjected to anisotropic etching to form a sidewall SW at the side wall of the gate electrode G1 and at the side wall of the gate electrode G2. Although the sidewall SW is designed to be formed from a single-layer film of the silicon nitride film, it is not limited thereto, but the silicon oxide film or the silicon oxynitride film may be used. Further, the sidewall SW made of a laminated film prepared by combining any of a silicon nitride film, a silicon oxide film and a silicon oxynitride film can be formed. As described above, at the main face of the semiconductor substrate 1S, the silicon nitride film SN1a is formed, and, by subjecting the silicon nitride film SN1a to an anisotropic etching, the sidewall SW made of the silicon nitride film SN1a is formed at the side wall of the gate electrode G1 and the side wall of the gate electrode G2.

Subsequently, as shown in FIG. 8, a deep n-type impurity diffusion region NR in alignment with the sidewall SW is formed at the n-channel type MISFET-forming region by using a photolithographic technique and an ion implantation method. The deep n-type impurity diffusion region NR is a semiconductor region. By the deep n-type impurity diffusion region NR and the shallow n-type impurity diffusion region EX1, a source region is formed. Similarly, by the deep n-type impurity diffusion region NR and the shallow n-type impurity diffusion region EX1, a drain region is formed. Thus, by forming the source region and the drain region by the shallow n-type impurity diffusion region EX1 and the deep n-type impurity diffusion region NR, the source region and the drain region are allowed to have an LDD (Lightly Doped Drain) structure. That is, the concentration of the impurity introduced into the shallow n-type impurity diffusion region EX1 is lower than that of the impurity introduced into the deep n-type impurity diffusion region NR, and thereby the LDD structure capable of reducing electric field concentration under the end portion of the gate electrode G1 is formed.

On the other hand, a deep p-type impurity diffusion region PR in alignment with the sidewall SW is formed at the p-channel type MISFET-forming region by using a photolithographic technique and an ion implantation method. The deep p-type impurity diffusion region PR is a semiconductor region. The deep p-type impurity diffusion region PR and the shallow p-type impurity diffusion region EX2 form the source region. Similarly, the deep p-type impurity diffusion region PR and the shallow p-type impurity diffusion region EX2 form the drain region. Thus, by forming the source region and the drain region by the shallow p-type impurity diffusion region EX2 and the deep p-type impurity diffusion region PR, the source region and the drain region are allowed to have the LDD (Lightly Doped Drain) structure. That is, the concentration of the impurity introduced into the shallow p-type impurity diffusion region EX2 is lower than that of the impurity introduced into the deep n-type impurity diffusion region PR, and thereby the LDD structure capable of reducing electric field concentration under the end portion of the gate electrode G2 is formed.

After the formation of the deep n-type impurity diffusion region NR and the deep p-type impurity diffusion region PR as described above, a heat treatment at around 1000° C. is performed. As a result, the introduced impurity is activated.

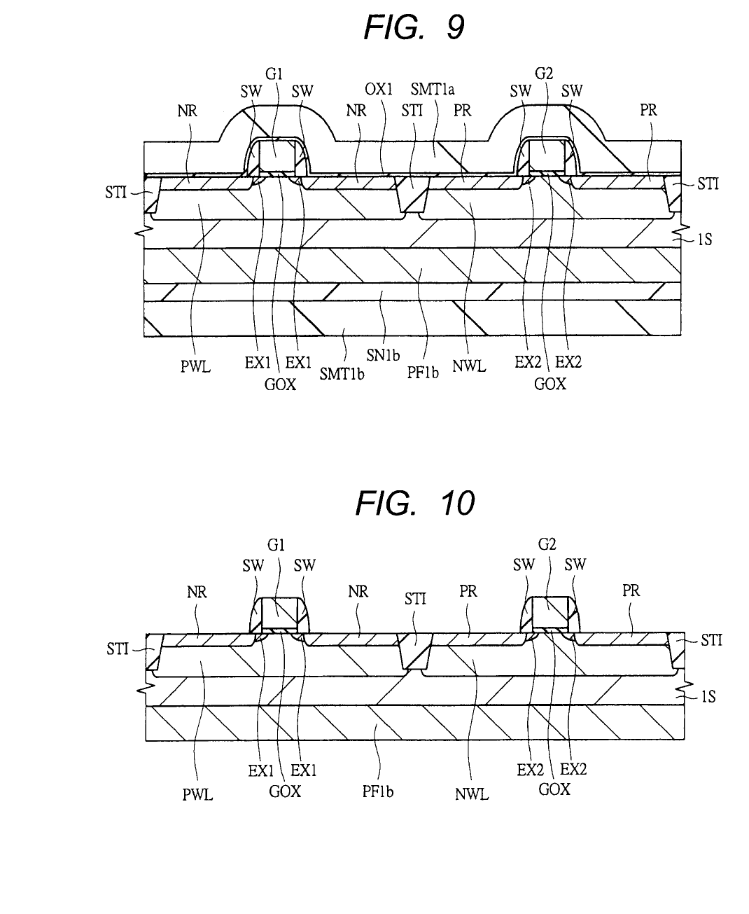

Next, as shown in FIG. 9, after the formation of a thin silicon oxide film OX1 over the main face of the semiconductor substrate 1S using, for example, a CVD method, a stressor film SMT1a is formed on the silicon oxide film OX1. The stressor film SMT1a can be formed by, for example, a CVD method using a batch-type deposition apparatus. As described above, since the stressor film SMT1a is formed by a batch-type deposition apparatus, a stressor film SMT1b is formed also at the back face of the semiconductor substrate 1S. The stressor film SMT1a and stressor film SMT1b are formed from, for example, the silicon nitride film.

The stressor film SMT1a being an insulating film has functions as shown below, which will be described. Recently, there is a strained silicon technique as a technology for attaining high performance of MISFETs. The strained silicon technique is a technique for improving the mobility of carriers (electrons or holes) that flow through the channel by applying stress caused by the strain at the channel-forming region of a MISFET. According to the strained silicon technique, it is possible to attain high performance of MISFETs by improving the mobility of carriers flowing through the channel. As described above, in the strained silicon technique, stress is generated at the semiconductor substrate, and one having the function of generating the stress is the aforementioned stressor film SMT1a. The stressor film SMT1a is formed from, for example, the silicon nitride film. Accordingly, by forming the stressor film SMT1a over the semiconductor substrate 1S, stress is generated caused by the difference between the lattice interval of the silicon nitride film and the lattice interval of silicon constituting the semiconductor substrate 1S, and the stress can generate a stress at the channel of the semiconductor substrate.

At this time, the stressor film SMT1a made of a silicon nitride film, over the main face of the semiconductor substrate 1S, is a film formed for applying strain to the channel-forming region in the semiconductor substrate 1S. Consequently, the stressor film SMT1a needs to have some degree of thickness so as to apply sufficient strain to the channel-forming region in the semiconductor substrate 1S. Consequently, as the formation method of the stressor film SMT1a, a batch-type deposition apparatus, which can easily form a silicon nitride film having a sufficient thickness and can attain the improvement in the throughput, is used. When forming the stressor film SMT1a made of the silicon nitride film at the main face of the semiconductor substrate 1S using the batch-type deposition apparatus, inevitably, the stressor film SMT1b made of the silicon nitride film is formed also at the back face of the semiconductor substrate 1S. As the result, at the back face of the semiconductor substrate 1S, there are formed the polysilicon film PF1b, the silicon nitride film SN1b formed on the polysilicon film PF1b, and the stressor film SMT1b formed on the silicon nitride film SN1b.

Subsequently, as shown in FIG. 10, the stressor film SMT1a formed over the main face of the semiconductor substrate 1S is removed. The removal of the stressor film SMT1a is practiced by wet etching with hot phosphoric acid. At this time, since not only the main face of the semiconductor substrate 1S but also the back face of the semiconductor substrate 1S is exposed to the hot phosphoric acid, not only the stressor film SMT1a formed at the main face of the semiconductor substrate 1S but also the stressor film SMT1b formed at the back face of the semiconductor substrate 1S is removed. At this time, at the back face of the semiconductor substrate 1S, the silicon nitride film SN1b is formed under the stressor film SMT1b. However, since the stressor film SMT1b is also formed from the silicon nitride film, when the stressor film SMT1b made of the silicon nitride film is removed, the silicon nitride film SN1b, which is formed from the silicon nitride film as is the case for the stressor film SMT1b, is also removed. Consequently, after the process of removing the stressor film SMT1a and the stressor film SMT1b, since the stressor film SMT1b and the silicon nitride film SN1b are removed from the back face of the semiconductor substrate 1S, the polysilicon film PF1b is exposed.

Here, such a question occurs that, when the stressor film SMT1a formed at the main face of the semiconductor substrate 1S by hot phosphoric acid is removed, the sidewall SW formed at the side wall of the gate electrode G1 and at the side wall of the gate electrode G2 might also be removed. That is, it is thought that the sidewall SW is also removed together when the stressor film SMT1a made of the silicon nitride film is removed, because the sidewall SW is formed also from the silicon nitride film. However, in Embodiment 1, the thin silicon oxide film OX1 is formed before the formation of the stressor film SMT1a. Therefore, the silicon oxide film OX1 functions as an etching stopper upon etching the stressor film SMT1a, to protect the sidewall SW made of the silicon nitride film. That is, the silicon oxide film OX1 formed over the main face of the semiconductor substrate 1S is formed in order to constitute the etching stopper upon etching and removing the stressor film SMT1a formed on the silicon oxide film OX1. Since the silicon oxide film OX1 is formed over the main face of the semiconductor substrate 1S, even when removing the stressor film SMT1a from the silicon nitride film, it is possible to protect and leave the sidewall SW constituted of the silicon nitride film of the same type. The silicon oxide film OX1 is a very thin film, and therefore is removed by a washing treatment or the like that is practiced after the stressor film SMT1a and stressor film SMT1b are removed.

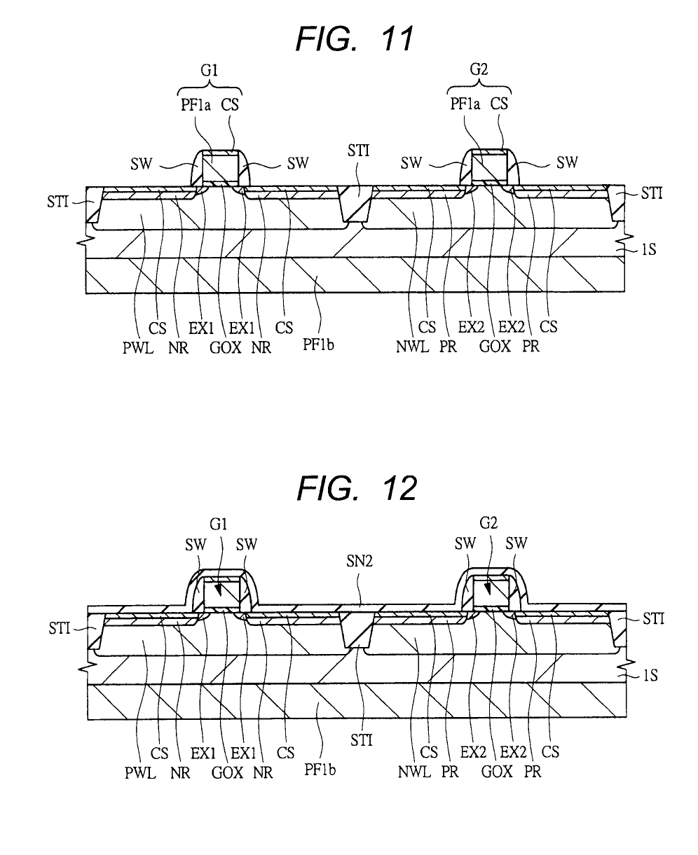

After that, as shown in FIG. 11, a nickel film is formed over the semiconductor substrate 1S. At this time, the nickel film is formed so as to directly contact the gate electrode G1 and gate electrode G2. Similarly, the nickel film also directly contacts the surface of the deep n-type impurity diffusion region NR and the surface of the deep p-type impurity diffusion region PR.

The nickel film can be formed using, for example, a sputtering method. Then, after the formation, the nickel film is subjected to a heat treatment to be allowed to react with the polysilicon film PF1a constituting the gate electrode G1 and gate electrode G2, thereby forming a nickel silicide film CS. As a result, the gate electrode G1 and gate electrode G2 have a laminated structure of the polysilicon film PF1a and the nickel silicide film CS. The nickel silicide film CS is formed for a purpose of reducing the resistance of the gate electrode G1 and gate electrode G2. Similarly, silicon and the nickel film are also reacted by the aforementioned heat treatment at the surface of the deep n-type impurity diffusion region NR and at the surface of the deep p-type impurity diffusion region PR, to form the nickel silicide film CS. Consequently, the resistance reduction can be attained also in the source region and drain region.

Then, an unreacted nickel film is removed from over the semiconductor substrate 1S. Meanwhile, although Embodiment 1 is so constituted as forming the nickel silicide film CS, but, it is also possible to form, for example, a cobalt silicide film, a titanium silicide film, or a platinum silicide film, in place of the nickel silicide film CS.

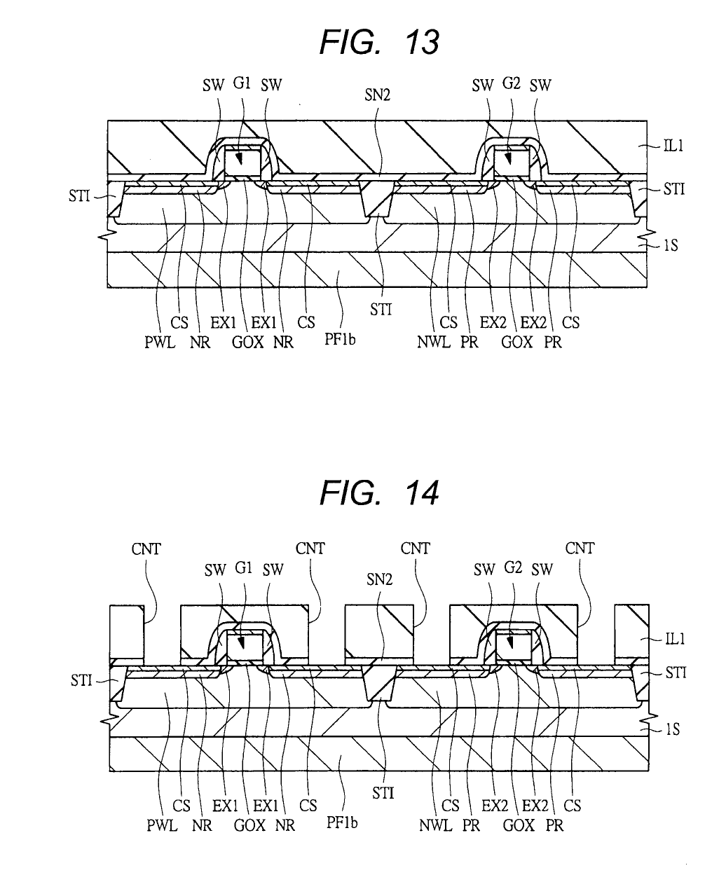

Next, as shown in FIG. 12, a silicon nitride film SN2 that covers the gate electrode G1 and the gate electrode G2 is formed over the main face of the semiconductor substrate 1S. As shown in FIG. 13, on the silicon nitride film SN2, an interlayer insulating film IL1 made of, for example, a silicon oxide film is formed. As described above, firstly the silicon nitride film SN2 is formed over the semiconductor substrate 1S including a region between the gate electrode G1 and the gate electrode G2, and, after that, on the silicon nitride film SN2, the interlayer insulating film IL1 is formed. Consequently, after that, a contact hole passing through the interlayer insulating film IL1 and the silicon nitride film SN2 is formed at the interlayer insulating film IL1, and, by the formation of the silicon nitride film SN2 as the under layer of the interlayer insulating film IL1, such an effect is obtained as suppressing short circuit defect between the gate electrode G1 or G2, and an electroconductive material embedded into the contact hole, caused by the displacement of the contact hole. That is, the silicon nitride film SN2 being an insulating film functions as an etching stopper film. The technique is referred to as so-called SAC (Self Align Contact). That is, the silicon nitride film SN2 formed over the semiconductor substrate 1S including the region between the gate electrode G1 and the gate electrode G2 is one that has such function as realizing the SAC technique, and as capable of suppressing the generation of defect caused by the displacement of the contact hole.

The silicon nitride film SN2 is formed by, for example, a CVD method using a single-wafer type deposition apparatus. The reason of using the single-wafer type deposition apparatus instead of a batch-type deposition apparatus for forming the silicon nitride film SN2 on this occasion is as follows. That is , when a heat treatment temperature is compared between the batch-type deposition apparatus and the single-wafer type deposition apparatus, the heat treatment temperature of the batch-type deposition apparatus is apt to be higher than that of the single-wafer type deposition apparatus. Here, the formation of the silicon nitride film SN2 for the SAC is a process that is practiced after the formation of the nickel silicide film CS, as described above. When a heat load of high temperature is applied to the nickel silicide film CS, the re-agglutination might occur in the nickel silicide film CS to generate such failure as breaking of wire. Accordingly, in processes after forming the nickel silicide film CS, it is desirable not to perform a heat treatment at high temperatures, if possible. As the result of the above consideration, the formation of the silicon nitride film SN2, which is practiced after the formation of the nickel silicide film CS, is desirably performed also at a temperature as low as possible. Consequently, for forming the silicon nitride film SN2, a single-wafer type deposition apparatus, in which the heat treatment temperature is low, is used. Further, the silicon nitride film SN2 for SAC additionally has such function as applying stress to the semiconductor substrate 1S by the strained silicon technique. Accordingly, in the formation of the silicon nitride film SN2 for SAC, it is necessary to employ a low heat treatment temperature and to apply stress to the film itself. In order to realize the silicon nitride film SN2 having such function, the use of the single-wafer type deposition apparatus is necessary. That is, in Embodiment 1, from the standpoint of employing a low heat treatment temperature and favorably forming the silicon nitride film SN2 for SAC capable of holding sufficient stress in the film, the single-wafer type deposition apparatus instead of the batch-type deposition apparatus is used for forming the silicon nitride film SN2 for SAC. As described above, in the process for forming the silicon nitride film SN2 at the main face of the semiconductor substrate 1S, the single-wafer type deposition apparatus is used. Therefore, the back face of the semiconductor substrate 1S is in such state that no silicon nitride film is formed and the polysilicon film PF1b is left to be exposed.

On the silicon nitride film SN2 for SAC, the interlayer insulating film IL1 is formed, which is formed from, for example, the silicon oxide film. Specifically, it has a laminated structure of a silicon oxide film formed by a CVD method using ozone and TEOS (tetra ethyl ortho silicate) as starting materials, and a silicon oxide film formed by a plasma CVD method using TEOS as a starting material.

Subsequently, as shown in FIG. 14, a contact hole CNT that penetrates through the interlayer insulating film IL1 and the silicon nitride film SN2 and arrives at the semiconductor substrate 1S is formed by using a photolithographic technique and an etching technique. The contact hole CNT is formed by firstly etching the interlayer insulating film IL1, and then etching the silicon nitride film SN2. As the result, the silicon nitride film SN2 functions as an etching stopper upon etching the interlayer insulating film IL1 made of the silicon oxide film, thereby giving such effect as suppressing the generation of defect caused by the displacement of the contact hole CNT.

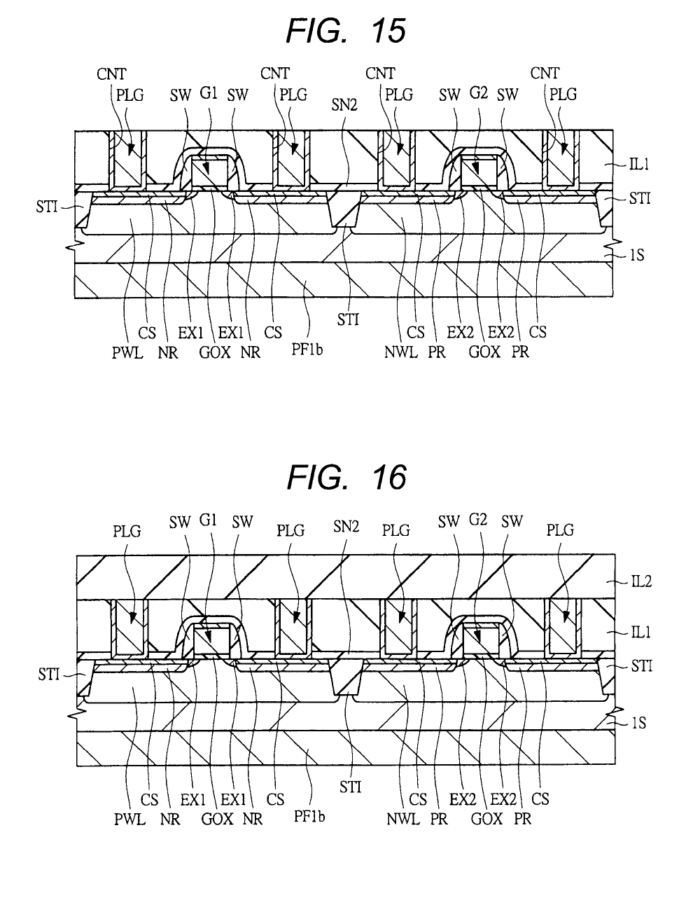

Next, as shown in FIG. 15, a titanium/titanium nitride film is formed on the interlayer insulating film IL1 including the bottom face and the inner wall of the contact hole CNT. The titanium/titanium nitride film is constituted of a laminated film of a titanium film and a titanium nitride film formed thereon, which can be formed by using, for example, a sputtering method. The titanium/titanium nitride film has so-called barrier properties that prevent the diffusion of tungsten, which is the material of a film to be embedded in a later process, into silicon, and that prevent damage given to a silicon material by the attack of fluoride to the silicon material upon forming a tungsten film by a CVD method using tungsten hexafluoride (WF₆).

Subsequently, a tungsten film is formed at the whole face of the main face of the semiconductor substrate 1S so as to be embedded into the contact hole CNT. The tungsten film can be formed using, for example, a CVD method. Further, by removing the unnecessary titanium/titanium nitride film and the tungsten film formed over the interlayer insulating film IL1 by, for example, a CMP method, a plug PLG can be formed.

After that, as shown in FIG. 16, over the interlayer insulating film IL1 at which the plug PLG has been formed, an interlayer insulating film IL2 is formed. The interlayer insulating film IL2 is formed from a low-permittivity film having a lower permittivity than, for example, the silicon oxide film. By the formation of the interlayer insulating film IL2 from a low-permittivity film as described above, the parasitic capacitance between wirings formed at the interlayer insulating film IL2 can be reduced. As the result, the delay of signals transmitted through the wiring can be suppressed. Examples of the low-permittivity film constituting the interlayer insulating film IL2 include an insulating film having specific permittivity of 3 or less. Specifically, the low-permittivity film can be constituted from an SiOC film, an HSQ (hydrogen silsesquioxane) film, an MSQ (methyl silsesquioxane) film or the like.

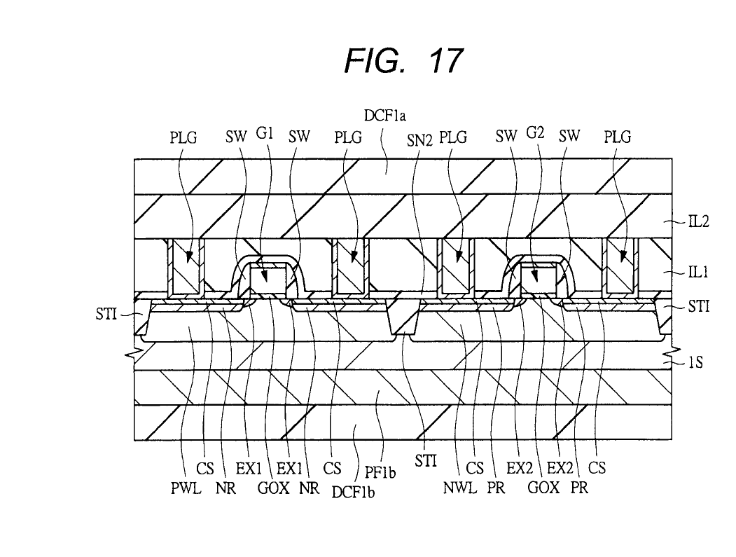

Next, as shown in FIG. 17, at both the main face and the back face of the semiconductor substrate 1S, a copper diffusion prevention film is formed. Specifically, the copper diffusion prevention film formed at the main face of the semiconductor substrate 1S is denoted by a copper diffusion prevention film DCF1a, and the copper diffusion prevention film formed at the back face of the semiconductor substrate 1S is denoted by a copper diffusion prevention film DCF1b. Embodiment 1 is characterized in that the copper diffusion prevention film DCF1b is formed at the back face of the semiconductor substrate 1S. By forming the copper diffusion prevention film DCF1b at the back face of the semiconductor substrate 1S as described above, it is possible to prevent the diffusion of copper atoms (including copper compounds) from the back face of the semiconductor substrate 1S. That is, as described later, at the interlayer insulating film IL2, copper wiring is formed by a damascene method, and, in the formation process of the copper wiring, copper atoms adhere to the back face of the semiconductor substrate 1S. Then, the copper atom adhering to the back face of the semiconductor substrate 1S diffuses in the semiconductor substrate 1S (silicon) by various heat treatments, which might degrade electric properties of a MISFET formed at the main face of the semiconductor substrate 1S. Although the polysilicon film PF1b has been formed at the back face of the semiconductor substrate 1S, the polysilicon film PF1b is a polycrystalline film and, therefore, a grain boundary exists between multiple crystalline grains. Consequently, the grain boundary works as a diffusion path of copper atoms and the copper atom diffuses into the semiconductor substrate 1S.

However, in Embodiment 1, prior to the formation process of the copper wiring, the copper diffusion prevention film DCF1b is formed at the back face of the semiconductor substrate 1S. Consequently, even when copper atoms adhere to the back face of the semiconductor substrate 1S in the formation process of the copper wiring, the copper diffusion prevention film DCF1b can suppress the diffusion of the copper atom into the silicon. Therefore, the performance degradation of MISFETs caused by the diffusion of the copper atom can be prevented.

As described above, since the copper diffusion prevention film DCF1b needs to have a function of preventing the diffusion of copper atoms, it needs to be formed from a denser film as compared with, for example, polycrystalline films such as the polysilicon film PF1b. That is, by forming the copper diffusion prevention film DCF1b from a dense film, it is possible to reduce the room for the diffusion of the copper atom into the semiconductor substrate 1S via the copper diffusion prevention film DCF1b. Specifically, the copper diffusion prevention film DCF1b can be formed from any of a silicon nitride film, a silicon carbonitride film, a silicon oxynitride film, and a silicon oxide film.

Here, Embodiment 1 is characterized in that the copper diffusion prevention film DCF1b is formed at the back face of the semiconductor substrate 1S. However, the formation of the copper diffusion prevention film DCF1b only at the back face of the semiconductor substrate 1S is practically difficult. Because, in order to form the copper diffusion prevention film DCF1b only at the back face of the semiconductor substrate 1S, the use of a single-wafer type deposition apparatus is necessary, which brings the main face of the semiconductor substrate 1S to contact a stage upon placing the semiconductor substrate 1S on the stage in the single-wafer type deposition apparatus. That is, when placing the main face of the semiconductor substrate 1S so that it contacts the stage and the back face of the semiconductor substrate 1S faces a deposition space side, the main face of the semiconductor substrate 1S tends to be damaged. In other words, at the main face of the semiconductor substrate 1S, semiconductor elements (MISFETs) are formed, and, pressing the main face of the semiconductor substrate 1S to the stage may give damage to semiconductor elements such as MISFETs formed at the main face. Accordingly, the formation of the copper diffusion prevention film DCF1b only at the back face of the semiconductor substrate 1S is actually difficult. Therefore, in Embodiment 1, the copper diffusion prevention film DCF1a is formed not only at the back face of the semiconductor substrate 1S but also at the main face of the semiconductor substrate 1S using a batch-type deposition apparatus. As described above, in Embodiment 1, since the batch-type deposition apparatus is used, the copper diffusion prevention film DCF1b can be formed at the back face of the semiconductor substrate 1S without damaging the main face of the semiconductor substrate 1S. After the process, at the back face of the semiconductor substrate 1S, firstly the polysilicon film PF1b is formed, and the copper diffusion prevention film DCF1b is formed on the polysilicon film PF1b as a result.

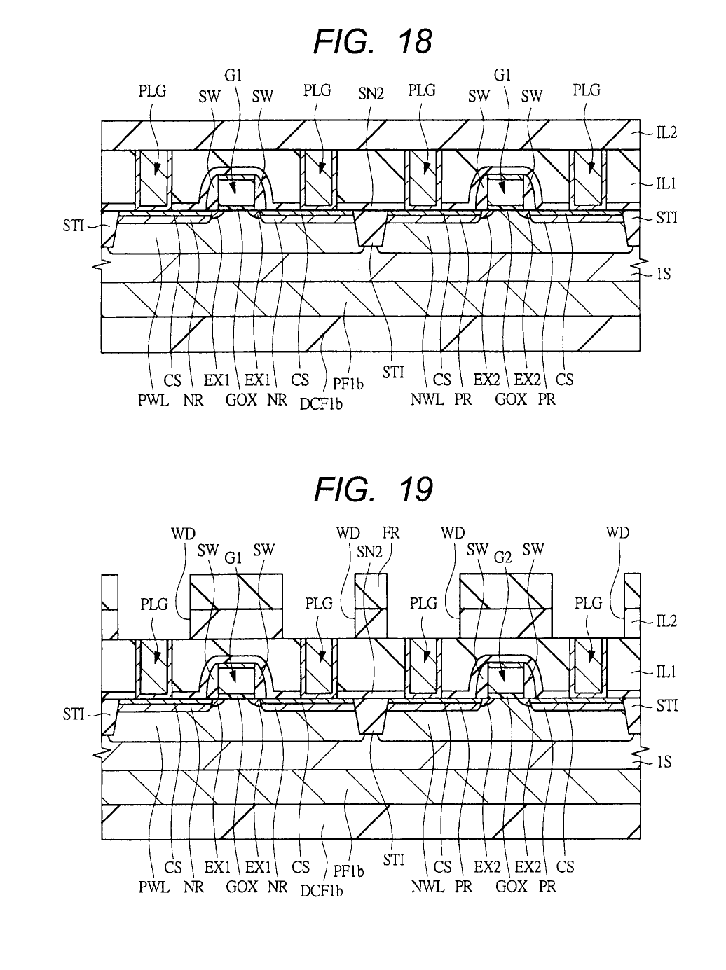

Subsequently, as shown in FIG. 18, the copper diffusion prevention film DCF1a formed over the main face side of the semiconductor substrate 1S is removed. Specifically, the copper diffusion prevention film DCF1a formed on the interlayer insulating film IL2 is removed using, for example, a CMP method. Then, further, a part of the interlayer insulating film IL2 is polished to make the interlayer insulating film IL2 have a thickness appropriate for the formation of the wiring layer.

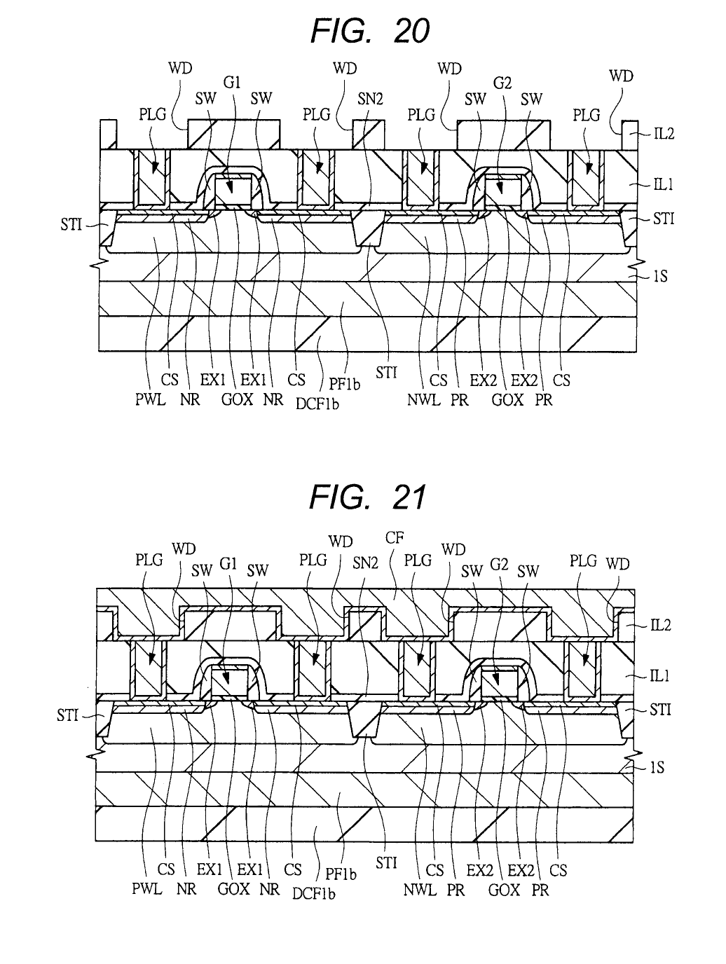

Next, as shown in FIG. 19, a wiring groove WD is formed at the interlayer insulating film IL2 by using a photolithographic technique and etching technique. Specifically, after coating a photoresist film FR on the interlayer insulating film IL2, the photoresist film FR is subjected to an exposure and development treatment to be patterned. The patterning of the photoresist film FR is performed so that an opening exists in a region for forming the wiring groove WD. Then, by the etching using the patterned photoresist film FR as a mask, the wiring groove WD is formed at the interlayer insulating film IL2. At the bottom portion of the wiring groove, for example, the surface of the plug PLG formed at the interlayer insulating film IL1 is exposed. After that, as shown in FIG. 20, the patterned photoresist film FR is removed by ashing or the like.

Then, as shown in FIG. 21, over the interlayer insulating film IL2 including the inside (the side face and bottom face) of the wiring groove WD, a barrier film BF made of a tantalum/tantalum nitride film (tantalum nitride and tantalum disposed on the tantalum nitride) is formed. The tantalum/tantalum nitride film being the barrier film BF can be formed by using, for example, a sputtering method. Meanwhile, the barrier film BF may be formed from a titanium/titanium nitride film (titanium nitride and titanium disposed on the titanium nitride) in place of the tantalum/tantalum nitride film. The barrier film BF is a film having a function of, after this process, preventing the diffusion of a copper material to be embedded inside the wiring groove WD into the semiconductor substrate 1S via the interlayer insulating film IL2.

Next, on the barrier film BF, a seed film (not shown) made of a thin copper film is formed. The seed film is formed by using, for example, a sputtering method. The seed film has a function of enabling the formation of a copper film in a subsequent electrolytic plating process to be performed easily, and also a function as an electrode in the electrolytic plating process. After that, a copper film CF is formed on the seed film. The copper film CF can be formed by, for example, an electrolytic plating method.

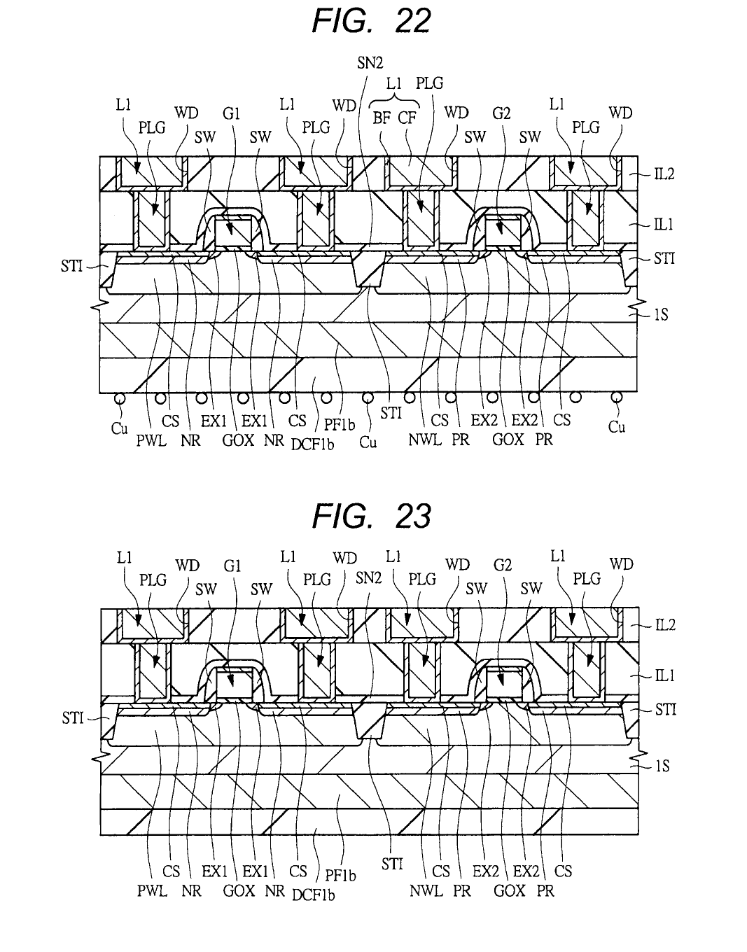

Subsequently, as shown in FIG. 22, the unnecessary copper film CF and the barrier film BF formed over the interlayer insulating film IL2 are removed by a CMP method, and the barrier film BF and the copper film CF are left only in the wiring groove WD, to form a wiring L1, in which the copper film CF is embedded into the wiring groove WD. The CMP method used at this time is a method of, for example, polishing the semiconductor substrate (the semiconductor wafer) 1S stuck to a spindle by pressing it to a polishing pad, while pouring a polishing liquid (slurry) containing silica particles to the surface of the semiconductor substrate 1S. The CMP method uses both a chemical mechanism, in which the slurry oxidizes the copper film surface to be polished, and a mechanical mechanism, in which the slurry mechanically scrapes away the oxidized layer. That is, since a CMP method uses a large amount of slurry being liquid, as shown in FIG. 22, a large amount of copper atoms Cu contained in the slurry adhere also to the back face of the semiconductor substrate 1S.

However, in Embodiment 1, at the back face of the semiconductor substrate 1S, the copper diffusion prevention film DCF1b has been formed. Consequently, for the back face of the semiconductor substrate 1S, a large amount of copper atoms Cu adhere to the surface where the copper diffusion prevention film DCF1b is exposed. However, since the copper diffusion prevention film DCF1b is constituted from a film having a high denseness, the copper atom Cu adhering to the surface of the copper diffusion prevention film DCF1b cannot intrude into the copper diffusion prevention film DCF1b. As the result, it is possible to prevent the diffusion of the copper atom Cu adhering to the surface of the copper diffusion prevention film DCF1b into the semiconductor substrate 1S via the copper diffusion prevention film DCF1b.

After that, as shown in FIG. 23, the semiconductor substrate 1S is subjected to a washing treatment. This can remove the copper atom Cu adhering to the surface of the copper diffusion prevention film DCF1b, for the back face of the semiconductor substrate 1S. For details, by lifting off a part of the copper diffusion prevention film DCF1b formed at the back face of the semiconductor substrate 1S, the copper atom Cu adhering to the surface of the copper diffusion prevention film DCF1b is removed effectively. That is, in the washing process, by removing a film by an amount corresponding to a very small thickness from the surface of the copper diffusion prevention film DCF1b, the copper atom Cu adhering to the surface of the copper diffusion prevention film DCF1b can be removed sufficiently. As the result, since the amount of copper atoms Cu remaining on the back face of the semiconductor substrate 1S is reduced, and the copper diffusion prevention film DCF1b inhibiting the intrusion of the copper atom Cu into the semiconductor substrate 1S has been formed, the diffusion of the copper atom Cu into the semiconductor substrate 1S can be suppressed sufficiently. Accordingly, the degradation of electric properties (such as insulation resistance) of the semiconductor element (MISFET) caused by the diffusion of the copper atom Cu can be suppressed.

After that, a multi-layer wiring is formed over the wiring L1, but the description thereof is omitted here. Here, each of multi-layer wirings is a copper wiring, which is formed by embedding copper metal into a groove by a plating method, and, after that, removing an excessive copper metal by a CMP method to form the copper wiring in the groove. Thus, finally the semiconductor device in Embodiment 1 can be formed. Meanwhile, in respective processes for the multi-layer wiring, a washing treatment for lifting off a part of the copper diffusion prevention film DCF1b is practiced. Therefore, the whole thickness of the copper diffusion prevention film DCF1b needs to be a thickness that will not disappear in multiple lift off treatments corresponding to the number of layers of the multi-layer wiring.

The characteristic of Embodiment 1 lies in that the copper diffusion prevention film DCF1b is formed at the back face of the semiconductor substrate 1S prior to the formation process of the copper wiring, and the characteristic constitution becomes a technical idea having a great meaning in a manufacturing process of the semiconductor device premising that the process, in which the strained silicon technique is practiced, is included. That is, since Embodiment 1 employs the strained silicon technique, for example, as shown in FIG. 9, at the main face of the semiconductor substrate 1S, the stressor film SMT1a is formed, and, at the back face of the semiconductor substrate 1S, the stressor film SMT1b is formed. Then, after applying stresses to the channel-forming region of the semiconductor substrate 1S, the stressor film SMT1a formed at the main face of the semiconductor substrate 1S and the stressor film SMT1b formed at the back face of the semiconductor substrate 1S are removed. At this time, for the back face of the semiconductor substrate 1S, since the stressor film SMT1b is formed from a silicon nitride film, similarly, the silicon nitride film SN1b also formed from a silicon nitride film is removed. Exactly the existence of the point makes the technical idea in Embodiment 1 important.

That is, when the strained silicon technique is not used, the stressor film SMT1a is never formed at the main face of the semiconductor substrate 1S, and the removal of the stressor film SMT1a formed at the main face is also unnecessary. This means that, when the strained silicon technique is not used, at the back face of the semiconductor substrate 1S, the stressor film SMT1b is not formed, too, and only the polysilicon film PF1b and the silicon nitride film SN1b formed on the polysilicon film PF1b have been formed. That is, exactly the use of the strained silicon technique enables the removal of the silicon nitride film SN1b formed at the back face of the semiconductor substrate 1S. In other words, when the strained silicon technique is not used, at the back face of the semiconductor substrate 1S, the silicon nitride film SN1b is left as it stands. The silicon nitride film SN1b is not removed later, and exists until the process for forming the copper wiring. Accordingly, when the strained silicon technique is not used, the silicon nitride film SN1b functions as a copper diffusion prevention film. Consequently, the necessity for especially forming, newly, the copper diffusion prevention film DCF1b at the back face of the semiconductor substrate 1S before the formation of the copper wiring, as is the case for Embodiment 1, becomes low.

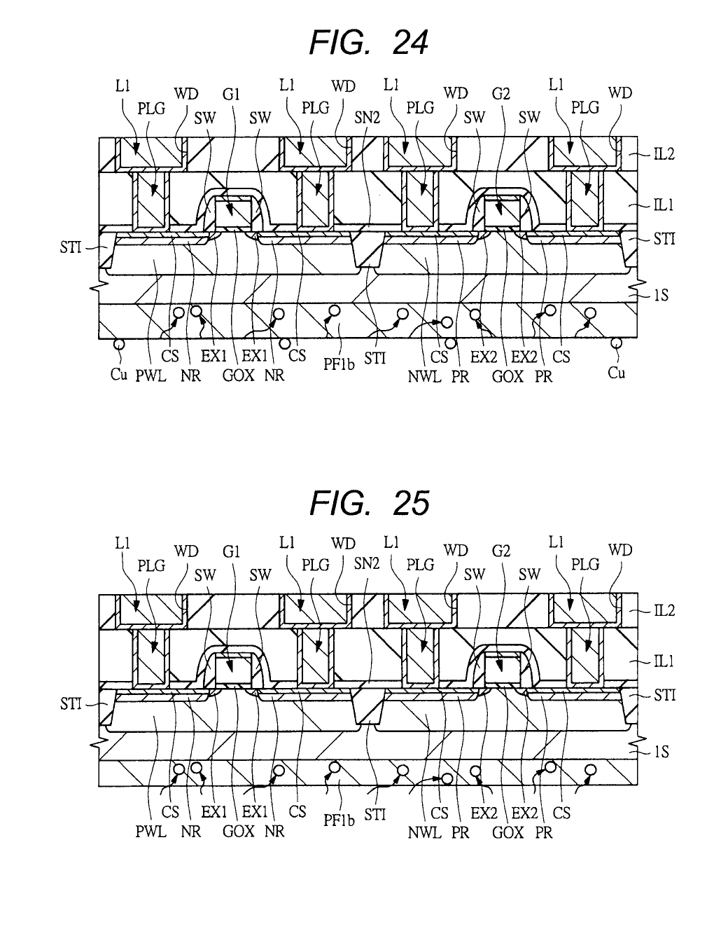

In contrast, when the strained silicon technique begins to be used for improving the current driving power of a MISFET, for example, as shown in FIG. 10, the silicon nitride film SN1b formed at the back face of the semiconductor substrate 1S is also removed. As the result, when the strained silicon technique is used, the process of forming the copper wiring is practiced while keeping the state in which polysilicon film PF1b is exposed on the back face of the semiconductor substrate 1S. At this time, suppose that the copper wiring is formed in the state in which the polysilicon film PF1b is exposed on the back face of the semiconductor substrate 1S as shown in FIG. 24. On this occasion, in a CMP method used in the formation process of the copper wiring, copper atoms Cu mixed in the slurry will adhere to the surface of the polysilicon film PF1b formed at the back face of the semiconductor substrate 1S. Then, the copper atom Cu adhered to the surface of the polysilicon film PF1b easily diffuses into the polysilicon film PF1b passing through innumerable grain boundaries existing in polycrystal. After that, as shown in FIG. 25, the copper atom Cu adhering to the surface of the polysilicon film PF1b is removed by a washing treatment. Copper atoms Cu to be removed by the washing treatment is only those existing near the surface of the polysilicon film PF1b, and copper atoms Cu having diffused into the polysilicon film PF1b are not removed but are left as they are in the polysilicon film PF1b. Then, by subsequent various heat treatments, copper atoms Cu having diffused into the polysilicon film PF1b further arrive at the MISFET-forming region formed at the main face side of the semiconductor substrate 1S via the inside of the semiconductor substrate 1S. As the result, electric properties of the MISFET such as insulation resistance degrade to lower the reliability of the semiconductor device. As described above, in the manufacturing process of a semiconductor device adopting the strained silicon technique, the copper atom Cu diffusing from the back face of the semiconductor substrate 1S gives great influence on the reliability of semiconductor devices.

Consequently, in Embodiment 1, the copper diffusion prevention film DCF1b is formed at the back face of the semiconductor substrate 1S before the process for forming the copper wiring, so as to be capable of preventing the diffusion of the copper atom Cu even in the manufacturing process of the semiconductor device that uses the strained silicon technique. This exerts such remarkable effect that the lowering of the reliability of semiconductor devices, which is caused by the diffusion of the copper atom Cu from the back face of the semiconductor substrate 1S to the inside of the semiconductor substrate 1S, can be prevented. That is, the technical idea in Embodiment 1 is one that is useful, particularly, on the premise of the technique that uses the strained silicon technique.

Further, the technical idea in Embodiment 1 will be discussed. As described above, when the strained silicon technique is used, as shown in FIG. 10, on the back face of the semiconductor substrate 1S, the polysilicon film PF1b is left to be exposed. Consequently, when the process for forming the copper wiring is practiced in the state, the copper atom Cu diffuses from the back face of the semiconductor substrate 1S to the inside of the semiconductor substrate 1S, to lower the reliability of the semiconductor device. Therefore, when considering processes after the process that used the strained silicon technique and before the process for forming the copper wiring, there is the process for forming the silicon nitride film SN2 for SAC (see FIG. 12). In the process, the silicon nitride film SN2 is formed at the main face of the semiconductor substrate 1S, and it is further considered that the silicon nitride film may be formed also at the back face of the semiconductor substrate 1S in the process.

That is, the silicon nitride film SN2 is formed by, for example, a CVD method with the deposition apparatus of a sheet-feed system, and, it is considered that, for example, when the silicon nitride film SN2 is formed with the batch-type deposition apparatus, the silicon nitride film may be formed also at the back face of the semiconductor substrate 1S in the process. However, on the basis of the reason shown below, for forming the silicon nitride film SN2 for SAC, the single-wafer type deposition apparatus instead of the batch-type deposition apparatus is employed. That is, when comparing the heat treatment temperature in the batch-type deposition apparatus and in the single-wafer type deposition apparatus, the heat treatment temperature in the batch-type deposition apparatus tends to become higher than that in the single-wafer type deposition apparatus. Here, the silicon nitride film SN2 for SAC is formed in the process that is practiced after the formation of the nickel silicide film CS. When a heat load of high temperature is applied to the nickel silicide film CS, the re-agglutination might occur in the nickel silicide film CS to generate such defect as the breaking of a wire. Accordingly, in processes after the formation of the nickel silicide film CS, it is desirable not to perform a heat treatment at high temperatures as far as possible. Consequently, the formation of the silicon nitride film SN2, too, which is practiced after the formation of the nickel silicide film CS, is desirably performed at low temperatures, if possible. Consequently, for forming the silicon nitride film SN2, the single-wafer type deposition apparatus with a low heat treatment temperature is used. Further, there is an additional reason shown below for using the single-wafer type deposition apparatus in the formation of the silicon nitride film SN2 for SAC. That is, the silicon nitride film SN2 for SAC additionally also has a function of applying stresses to the semiconductor substrate 1S, as the result of the strained silicon technique. Accordingly, the silicon nitride film SN2 for SAC needs to be formed at a low heat treatment temperature and to have stresses in the film itself. It is difficult to realize the silicon nitride film SN2 having the function using the batch-type deposition apparatus, and is necessary to use the single-wafer type deposition apparatus. That is, in Embodiment 1, the single-wafer type deposition apparatus instead of the batch-type deposition apparatus is used for forming the silicon nitride film SN2 for SAC, from the standpoint of favorably forming a film, which can sufficiently hold stresses in the film, at a low heat treatment temperature as the silicon nitride film SN2 for SAC.

Consequently, since the single-wafer type deposition apparatus is used in the process for forming the silicon nitride film SN2 at the main face of the semiconductor substrate 1S, for the back face of the semiconductor substrate 1S, no silicon nitride film is formed but the state, in which the polysilicon film PF1b is exposed, is maintained. Accordingly, it cannot be said that the formation of a silicon nitride film to be a copper diffusion prevention film at the back face of the semiconductor substrate 1S is desirable. Therefore, it is necessary to add a process for forming a copper diffusion prevention film as a new process, as is the case for Embodiment 1.

Here, in Embodiment 1, as shown in FIG. 17, at the main face of the semiconductor substrate 1S, the copper diffusion prevention film DCF1a is formed, and, at the back face of the semiconductor substrate 1S, the copper diffusion prevention film DCF1b is formed. At this time, the copper diffusion prevention film DCF1a and the copper diffusion prevention film DCF1b, which are characteristics of Embodiment 1, are formed by the batch-type deposition apparatus, which is practiced in a process after the silicide process. Accordingly, for example, when forming the copper diffusion prevention film DCF1a and the copper diffusion prevention film DCF1b formed from the silicon nitride film by the batch-type deposition apparatus, it is considered that the problem of the re-agglutination in the nickel silicide film CS might generate. As described above, in the instance of the silicon nitride film SN2 for SAC, the single-wafer type deposition apparatus, in which the heat treatment temperature in the deposition process can be lowered, is used from the standpoint of suppressing the re-agglutination in the nickel silicide film CS. In contrast, in the process for forming the copper diffusion prevention film DCF1a and the copper diffusion prevention film DCF1b that are characteristics of Embodiment 1, the batch-type deposition apparatus capable of forming the copper diffusion prevention film DCF1a and the copper diffusion prevention film DCF1b at both faces of the semiconductor substrate 1S, respectively, is used from the necessity of forming the copper diffusion prevention film DCF1b at the back face of the semiconductor substrate 1S. However, even if the copper diffusion prevention film DCF1a and the copper diffusion prevention film DCF1b are formed with the batch-type deposition apparatus, no problem of the re-agglutination in the nickel silicide film CS is revealed.

The reason is that the silicon nitride film SN2 for SAC and the copper diffusion prevention film DCF1b have film properties different from each other caused by the difference in the function of the silicon nitride film SN2 for SAC and the function of the copper diffusion prevention film DCF1b. That is, the silicon nitride film SN2 for SAC is required to be a film that has some degree of stress in the film. In order to form such film at a heat treatment temperature as low as possible, the single-wafer type deposition apparatus is suitable. Accordingly, the silicon nitride film SN2 for SAC is formed with the single-wafer type deposition apparatus.

On the other hand, the copper diffusion prevention film DCF1b, which is the characteristic of Embodiment 1, is not required to have stress generated in the film, in contrast to the silicon nitride film SN2 for SAC, and is a film that is sufficient only when it is formed at the back face of the semiconductor substrate 1S. That is, the copper diffusion prevention film DCF1b is sufficient only when it is formed at the back face of the semiconductor substrate 1S, and conditions required for the film properties thereof are eased as compared with those for the silicon nitride film SN2 for SAC. Accordingly, the copper diffusion prevention film DCF1b does not need to be formed similarly as the silicon nitride film SN2 for SAC, and the use of the batch-type deposition apparatus with a low heat treatment temperature does not generate any problem. In other words, the copper diffusion prevention film DCF1b is a film that is sufficient when it has such film properties that can be formed with the batch-type deposition apparatus placed in a state of low heat treatment temperature. Accordingly, even when forming the copper diffusion prevention film DCF1b with the batch-type deposition apparatus, the heat treatment temperature can be lowered, and, therefore, no such problem as the re-agglutination in the nickel silicide film CS is revealed.

Further, the technical idea in Embodiment 1 will be discussed. Here, the difference from Japanese Patent Laid-Open No. 2000-150640 (Patent Document 1) will be described. Patent Document 1 describes a technique of preventing performance degradation in elements caused by such metal contaminant as copper or a copper compound adhered to the back face of a semiconductor substrate, in a method of manufacturing a semiconductor device including a process for forming a copper-based metal film. Specifically, it describes that a barrier film such as a silicon oxide film is formed at the back face of the semiconductor substrate, and, after that, a copper-based metal film is formed at the main face of a semiconductor substrate.

At this time, the technical idea in Embodiment 1 has similarity to the technique of Patent Document 1 in that the copper diffusion prevention film (the barrier film) is formed at the back face of the semiconductor substrate 1S before the formation of the copper wiring. However, in Patent Document 1, the barrier film is formed only at the back face of the semiconductor substrate. However, it is actually difficult to form the barrier film only at the back face of the semiconductor substrate like this. Because, in order to form the barrier film only at the back face of the semiconductor substrate, it is necessary to use the single-wafer type deposition apparatus, but, in the single-wafer type deposition apparatus, the main face of a semiconductor substrate is caused to contact a stage upon placing the semiconductor substrate onto the stage. That is, when placing the semiconductor substrate so that the main face thereof contacts the stage in order and the back face thereof faces the deposition space side, the main face of the semiconductor substrate tends to be damaged. That is, at the main face of the semiconductor substrate, the semiconductor element (MISFET) is formed, and, pressing the main face of the semiconductor substrate to the stage causes damage to the semiconductor elements such as the MISFET formed at the main face. Accordingly, it is actually difficult to form the barrier film only at the back face of the semiconductor substrate. Consequently, the technique described in Patent Document 1 is not practical from the standpoint of applying it to actual manufacturing processes.

In contrast, in Embodiment 1, as shown in FIG. 17, the copper diffusion prevention film DCF1a is formed also at the main face of the semiconductor substrate 1S, not only at the back face of the semiconductor substrate 1S, using the batch-type deposition apparatus. Consequently, in Embodiment 1, it is possible to form the copper diffusion prevention film DCF1b at the back face of the semiconductor substrate 1S without damaging the main face of the semiconductor substrate 1S, because the batch-type deposition apparatus is used. After that, the copper diffusion prevention film DCF1a being formed at the main face of the semiconductor substrate 1S is removed. Accordingly, Embodiment 1 provides the technique that is useful from the standpoint of being applied to actual manufacturing processes. Consequently, the technical idea in Embodiment 1 and the technique described in Patent Document 1 include different method of manufacturing the copper diffusion prevention film (the barrier film). Based on the difference, the technical idea in Embodiment 1 is one that is easily applied to actual manufacturing processes, but, in contrast, the technique described in Patent Document 1 is one that is hardly applied to actual manufacturing processes. Since Japan Patent Law aims at the development of industries, a technique becomes useful only when it is easily applied to actual industrial technique. When taking this point into consideration, it is understood that the technical idea in Embodiment 1 corresponds to the purpose of the Patent Law, and that it is the technique that keeps a distance from the technique in Patent Document 1. That is, the technique described in Patent Document 1 is one that prevents the diffusion of copper atoms from the back face of a semiconductor substrate, but that generates such adverse effect as giving damage to semiconductor elements formed over the main face side of the semiconductor substrate. In contrast, the technical idea in Embodiment 1 is the one that exerts such remarkable effect as capable of suppressing the diffusion of copper atoms Cu from the back face of the semiconductor substrate 1S without giving damage to the semiconductor element (MISFET) formed over the main face side of the semiconductor substrate 1S. The remarkable difference in effects results from the difference in methods for manufacturing the copper diffusion prevention film (the barrier film).

Further, it is also said that the technical idea in Embodiment 1 premises that strained silicon technique is used. In contrast, Patent Document 1 neither describes nor suggests the strained silicon technique. Originally, as described in the present specification, when the strained silicon technique is not used, the silicon nitride film remains at the back face of the semiconductor substrate 1S, and forming the copper diffusion prevention film at the back face of the semiconductor substrate 1S by a new process has low usefulness. That is, Patent Document 1 that does not refer to the strained silicon technique can originally not recognize the problem that newly arises by the application of the strained silicon technique. In fact, as Embodiment 1, the recognition of the strained silicon technique leads for the first time to the recognition of usefulness of forming the copper diffusion prevention film DCF1b at the back face of the semiconductor substrate 1S. As described above, the technical idea in Embodiment 1 is completely different from the technique described in Patent Document 1, and, in addition, Patent Document 1 neither refers to the new subject (the problem generated caused by using the strained silicon technique) that is recognized in Embodiment 1, nor includes description that gives motivation to easily think of the technical idea in Embodiment 1. From above, it is clearly understood that the technical idea in Embodiment 1 is clearly different from the technique described in Patent Document 1, and that easily thinking of the technical idea in Embodiment 1 from the technique described in Patent Document 1 is difficult.

### Embodiment 2

In Embodiment 1, prior to the formation process of the copper wiring, the copper diffusion prevention film DCF1a is formed at the main face of the semiconductor substrate 1S, and the copper diffusion prevention film DCF1b is formed at the back face of the semiconductor substrate 1S. Then, after removing the copper diffusion prevention film DCF1a formed at the main face of the semiconductor substrate 1S, the formation process of the copper wiring is practiced. In contrast, Embodiment 2 is the same as Embodiment 1 in that the copper diffusion prevention film DCF1a is formed at the main face of the semiconductor substrate 1S, and that the copper diffusion prevention film DCF1b is formed at the back face of the semiconductor substrate 1S, prior to the formation process of the copper wiring. However, Embodiment 2 differs from Embodiment 1 in that the copper diffusion prevention film DCF1a formed at the main face of the semiconductor substrate 1S is used as a hard mask in the formation process of the copper wiring.

In the formation process of the copper wiring, for example, a damascene method is used. In the damascene method, an interlayer insulating film is formed over the semiconductor substrate, and, after that, by using a photolithographic technique and an etching technique, the wiring groove is formed at the interlayer insulating film. After that, a copper film is formed over the interlayer insulating film including the inside of the wiring groove, and an unnecessary copper film formed over the interlayer insulating film is removed by a CMP method, and the copper film remains only in the wiring groove. Thus, the wiring, in which the copper film is embedded into the wiring groove, can be formed.

In recent years, the downsizing and high integration are proceeding. Consequently, the fining of wiring is also proceeding. In order to correspond also to the fining of the wiring, the improvement in the processing accuracy of the wiring groove formed at the interlayer insulating film has been required. The wiring groove is formed by coating a photoresist film on the interlayer insulating film, after that, subjecting the photoresist film to an exposure and a development treatment, and performing the etching using the patterned photoresist film as a mask. Accordingly, the processing accuracy of the wiring groove is influenced by the processing accuracy of the photoresist film to be the mask. Consequently, from the standpoint of improving the processing accuracy of the photoresist film, a multi-layer resist film formation technique has been used, in which multiple photoresist films of different materials are formed into a multi-layer form. However, in the multi-layer resist film formation technique, a problem shown below is revealed.

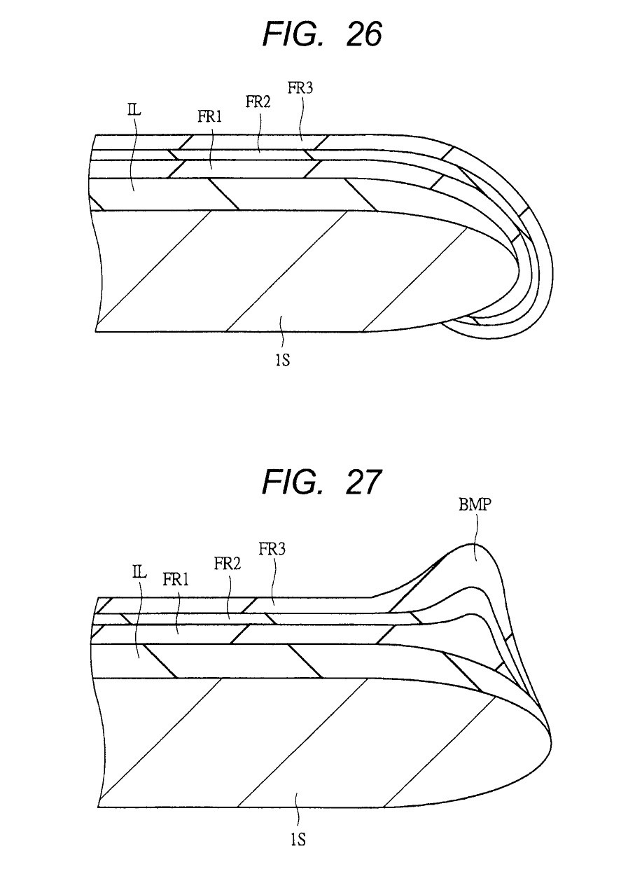

The problem will be described with reference to drawings. As shown in FIG. 26, after the formation of the interlayer insulating film IL over the semiconductor substrate 1S, a multi-layer resist film is formed on the interlayer insulating film IL. Specifically, a photoresist film FR1 is formed on the interlayer insulating film IL, and, on the photoresist film FR1, a photoresist film FR2 is formed. Further, on the photoresist film FR2, a photoresist film FR3 is formed. The photoresist films FR1 to FR3 are formed over the main face of the semiconductor substrate 1S, and, in the formation process, the photoresist films FR1 to FR3 are formed so as to wind around the back face of the semiconductor substrate 1S side, too, from the edge portion on the main face of the semiconductor substrate 1S side.

Since the photoresist films FR1 to FR3 formed at the edge portion of the main face of the semiconductor substrate 1S side and at the back face so as to wind around are at a high risk of peeling to form foreign materials, the removal thereof is performed. That is, after the formation of the photoresist films FR1 to FR3, the photoresist films FR1 to FR3 formed at the edge portion of the semiconductor substrate 1S and at the back face side winding around from the edge portion are removed in an edge rinse process. However, when the edge rinse process is practiced, as shown in FIG. 27, a blister portion BMP is formed at the edge portion on the main face of the semiconductor substrate 1S side.

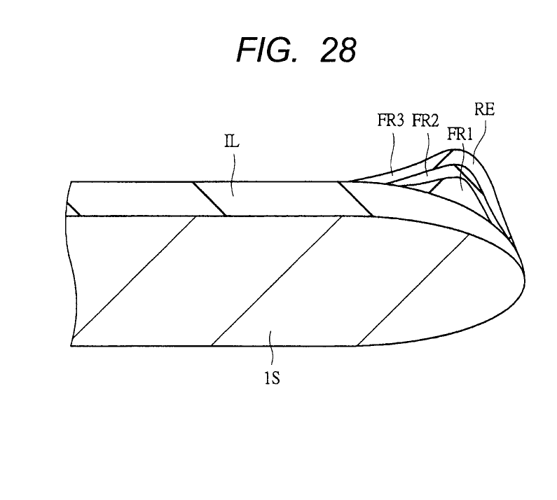

Generally, not limited to the multi-layer resist film formation technique, the edge rinse process is practiced after the formation of a photoresist film over the semiconductor substrate 1S, in order to remove the photoresist film formed at the edge portion of the main face side of the semiconductor substrate 1S and at the back face side by winding around from the edge portion. However, in the multi-layer resist film formation technique, since the photoresist films FR1 to FR3 formed into a multi-layer have a large total thickness, the formation of the blister portion BMP after the edge rinse process becomes remarkable. Then, as shown in FIG. 28, even after practicing the process for removing the photoresist films FR1 to FR3, a part of the blister portion BMP formed at the edge portion of the semiconductor substrate 1S remains as a residue RE. After that, the residue RE peels off when holding the semiconductor substrate 1S with a wafer holder, or the like, to be the cause of generating foreign materials. When using the multi-layer resist film, particularly, the size of the blister portion BMP becomes large, and, therefore, the residue RE remaining after the removal of photoresist films FR1 to FR3 also becomes remarkable, to increase the generation probability of foreign materials. The generation of foreign materials results in the inferiority of semiconductor devices caused by, for example, the adhesion over the semiconductor substrate 1S.

Therefore, Embodiment 2 premises that the multi-layer resist film formation technique is not used but a single-layer photoresist film is used. On this occasion, since the thickness of the photoresist film can be made small, it is possible to suppress the blister portion from being formed at the edge portion of the semiconductor substrate 1S, and to suppress the residue from remaining at the edge portion of the semiconductor substrate 1S after removing the photoresist film. As the result, the improvement in the yield of semiconductor devices can be expected. However, when using the single-layer photoresist film, it is necessary to devise the improvement in the processing accuracy. Embodiment 2 proposes the technique that enables the improvement in the processing accuracy to be expected even when the single-layer photoresist film is used.

Hereinafter, the manufacturing process of a semiconductor device in Embodiment 2 will be described with reference to drawings. In the manufacturing process of a semiconductor device in Embodiment 2, firstly, processes shown in FIGS. 1 to 16 in Embodiment 1 are practiced.

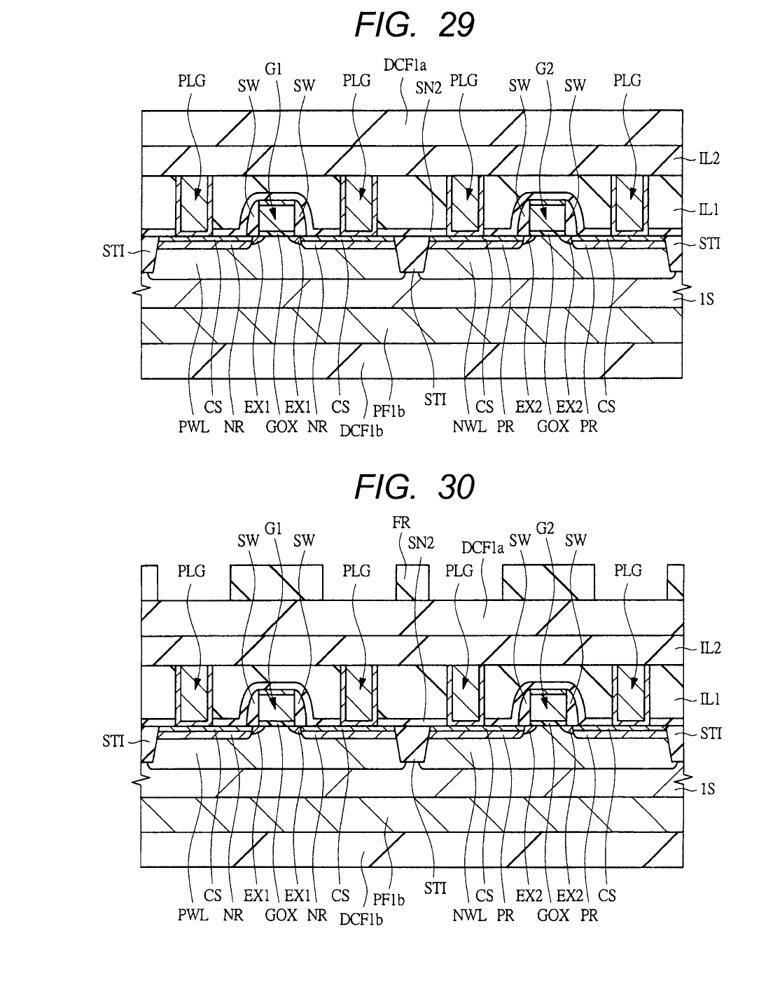

Subsequently, as shown in FIG. 29, at both the main face and the back face of the semiconductor substrate 1S, a copper diffusion prevention film is formed. Specifically, the copper diffusion prevention film formed at the main face of the semiconductor substrate 1S is denoted by a copper diffusion prevention film DCF1a, and the copper diffusion prevention film formed at the back face of the semiconductor substrate 1S is denoted by a copper diffusion prevention film DCF1b. Embodiment 2 is also characterized, as is the case for Embodiment 1, in that the copper diffusion prevention film DCF1b is formed at the back face of the semiconductor substrate 1S. By forming the copper diffusion prevention film DCF1b at the back face of the semiconductor substrate 1S as described above, it is possible to prevent the diffusion of copper atoms (including copper compounds) from the back face of the semiconductor substrate 1S. That is, as described later, at the interlayer insulating film IL2, copper wiring is formed by a damascene method, and, in the formation process of the copper wiring, copper atoms adhere to the back face of the semiconductor substrate 1S. Then, the copper atom adhering to the back face of the semiconductor substrate 1S diffuses in the semiconductor substrate 1S (silicon) by various heat treatments, which might degrade electric properties of a MISFET formed at the main face of the semiconductor substrate 1S. Although the polysilicon film PF1b has been formed at the back face of the semiconductor substrate 1S, the polysilicon film PF1b is a polycrystalline film and, therefore, a grain boundary exists between multiple crystalline grains. Consequently, the grain boundary works as a diffusion path of copper atoms and the copper atom diffuses into the semiconductor substrate 1S.

However, also in Embodiment 2, prior to the formation process of the copper wiring, the copper diffusion prevention film DCF1b is formed at the back face of the semiconductor substrate 1S. Consequently, even when copper atoms adhere to the back face of the semiconductor substrate 1S in the formation process of the copper wiring, the copper diffusion prevention film DCF1b can suppress the diffusion of the copper atom into the silicon. Therefore, the performance degradation of MISFETs caused by the diffusion of the copper atom can be prevented.

As described above, since the copper diffusion prevention film DCF1b needs to have a function of preventing the diffusion of copper atoms, it needs to be formed from a denser film as compared with, for example, polycrystalline films such as the polysilicon film PF1b. That is, by forming the copper diffusion prevention film DCF1b from a dense film, it is possible to reduce the room for the diffusion of the copper atom into the semiconductor substrate 1S via the copper diffusion prevention film DCF1b. Specifically, the copper diffusion prevention film DCF1b can be formed from any of a silicon nitride film, a silicon carbonitride film, and a silicon oxynitride film.

Embodiment 2 also forms the copper diffusion prevention film DCF1a not only at the back face of the semiconductor substrate 1S but also at the main face of the semiconductor substrate 1S, by using the batch-type deposition apparatus. As described above, Embodiment 2, since the batch-type deposition apparatus is also used, can form the copper diffusion prevention film DCF1b at the back face of the semiconductor substrate 1S without damaging the main face of the semiconductor substrate 1S. After the process, at the back face of the semiconductor substrate 1S, firstly, the polysilicon film PF1b is formed, on which the copper diffusion prevention film DCF1b is formed.

Next, as shown in FIG. 30, on the copper diffusion prevention film DCF1a formed over the main face of the semiconductor substrate 1S side, the single-layer photoresist film FR is formed. At this time, the edge rinse process is practiced at the edge portion of the semiconductor substrate 1S, wherein, since the thickness of the single-layer photoresist film FR is smaller than the total thickness of the multi-layer resist film, the formation of the blister portion at the edge portion of the semiconductor substrate 1S can be suppressed. Further, since a photoresist up to three layers as shown in FIG. 26 and the like is not used, the cost can also be reduced. After that, the photoresist film FR is subjected to an exposure and a development treatment, to pattern the photoresist film FR. Here, under the photoresist film FR, the copper diffusion prevention film DCF1a (for example, a silicon nitride film, silicon carbonitride film, or silicon oxynitride film) is formed, and the copper diffusion prevention film DCF1a functions as an antireflection film. Consequently, the processing accuracy of the photoresist film FR is improved. That is, the characteristic of Embodiment 2 lies in that, since the copper diffusion prevention film DCF1a is not removed but is left, in contrast to Embodiment 1, and that the remaining copper diffusion prevention film DCF1a is allowed to function as the antireflection film. As the result, the processing accuracy of the photoresist film FR can be improved.

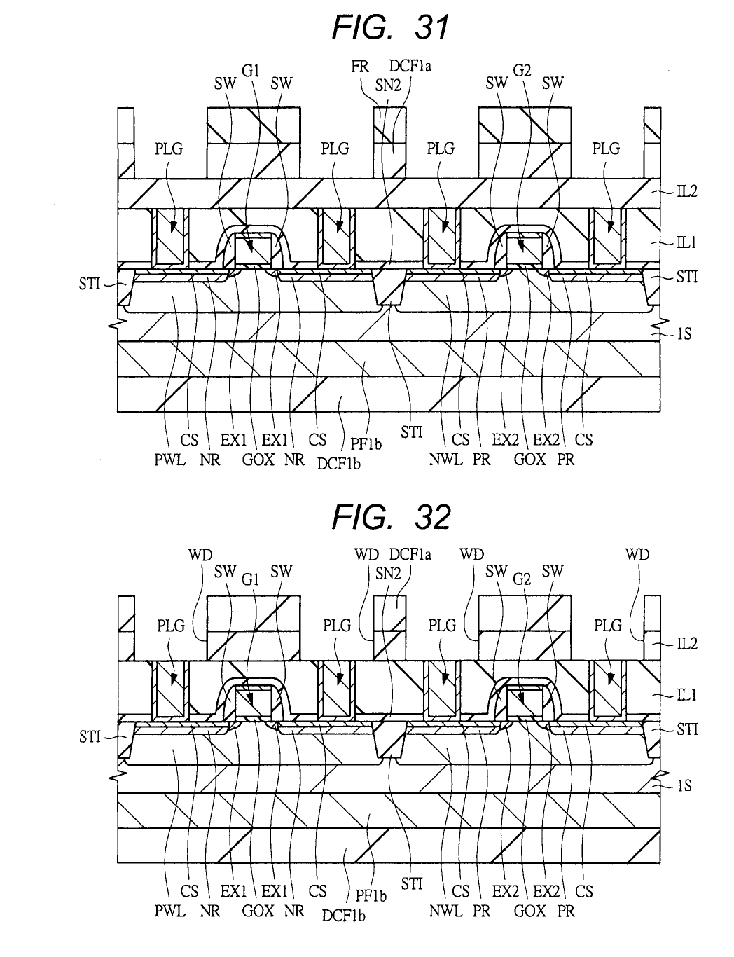

Subsequently, as shown in FIG. 31, the copper diffusion prevention film DCF1a is patterned by the etching while using the patterned photoresist film FR as a mask. After that, the patterned photoresist film FR is removed. At this time, in Embodiment 2, since the single-layer photoresist film FR is used, the blister portion at the edge portion of the semiconductor substrate 1S is suppressed, and the generation of the residue can be suppressed.

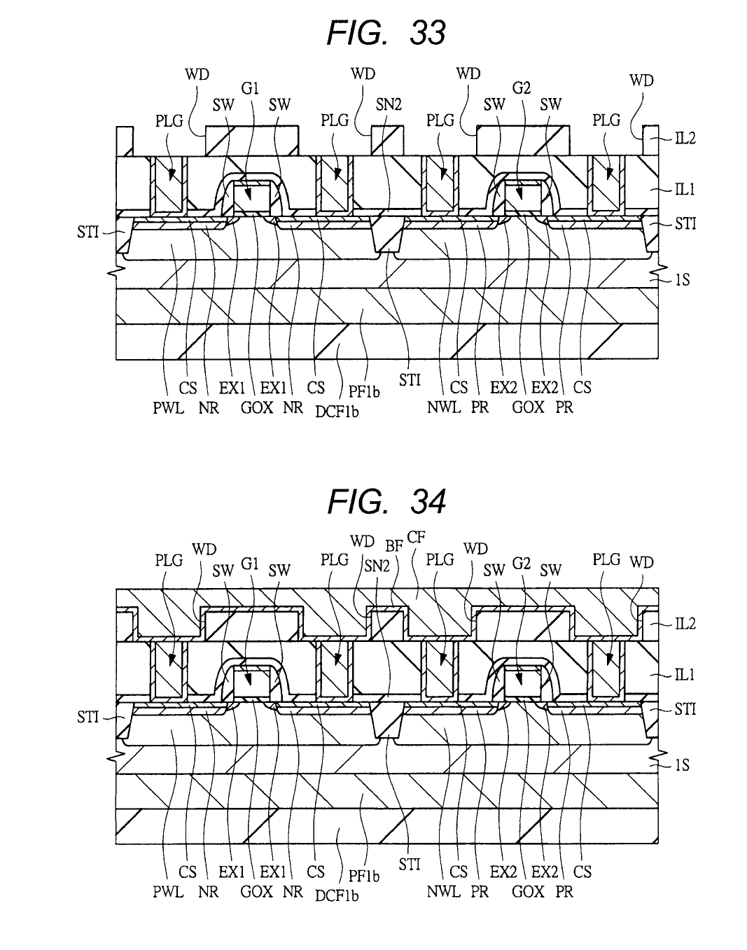

Then, as shown in FIG. 32, the wiring groove WD is formed at the interlayer insulating film IL2 by etching the interlayer insulating film IL2 while using the patterned copper diffusion prevention film DCF1a as a hard mask. After that, as shown in FIG. 33, the patterned copper diffusion prevention film DCF1a is removed.

Next, as shown in FIG. 34, over the interlayer insulating film IL2 including the inside (the side face and bottom face) of the wiring groove WD, a barrier film BF made of a tantalum/tantalum nitride film is formed. The tantalum/tantalum nitride film (tantalum nitride and tantalum disposed on the tantalum nitride) being the barrier film BF can be formed by using, for example, a sputtering method. Meanwhile, the barrier film BF can be formed from a titanium/titanium nitride film (titanium nitride and titanium disposed on the titanium nitride) in place of the tantalum/tantalum nitride film. The barrier film BF is a film having a function of, after this process, preventing the diffusion of a copper material embedded inside the wiring groove WD into the semiconductor substrate 1S via the interlayer insulating film IL2.

Next, on the barrier film BF, the seed film (not shown) made of a thin copper film is formed. The seed film is formed by using, for example, a sputtering method. The seed film has a function of enabling the formation of a copper film in a subsequent electrolytic plating process to be performed easily, and also a function as an electrode in the electrolytic plating process. After that, a copper film CF is formed on the seed film. The copper film CF can be formed by, for example, an electrolytic plating method.

Subsequently, as shown in FIG. 35, the unnecessary copper film CF and the barrier film BF formed over the interlayer insulating film IL2 are removed by a CMP method, and the barrier film BF and the copper film CF are left only in the wiring groove WD, to form a wiring L1, in which the copper film CF is embedded into the wiring groove WD. The CMP method used at this time is a method of, for example, polishing the semiconductor substrate 1S stuck to a spindle by pressing it to a polishing pad, while pouring a polishing liquid (slurry) containing silica particles to the surface of the semiconductor substrate (the semiconductor wafer) 1S. The CMP method uses both a chemical mechanism, in which the slurry oxidizes the copper film surface to be polished, and a mechanical mechanism, in which the slurry mechanically scrapes away the oxidized layer. That is, since a CMP method uses a large amount of slurry being liquid, as shown in FIG. 35, a large amount of copper atoms Cu contained in the slurry adhere also to the back face of the semiconductor substrate 1S.

However, also in Embodiment 2, at the back face of the semiconductor substrate 1S, the copper diffusion prevention film DCF1b has been formed. Consequently, for the back face of the semiconductor substrate 1S, a large amount of copper atoms Cu adhere to the surface where the copper diffusion prevention film DCF1b is exposed. However, since the copper diffusion prevention film DCF1b is constituted from a film having a high denseness, the copper atom Cu adhering to the surface of the copper diffusion prevention film DCF1b cannot intrude into the copper diffusion prevention film DCF1b. As the result, it is possible to prevent the diffusion of the copper atom Cu adhering to the surface of the copper diffusion prevention film DCF1b into the semiconductor substrate 1S via the copper diffusion prevention film DCF1b.

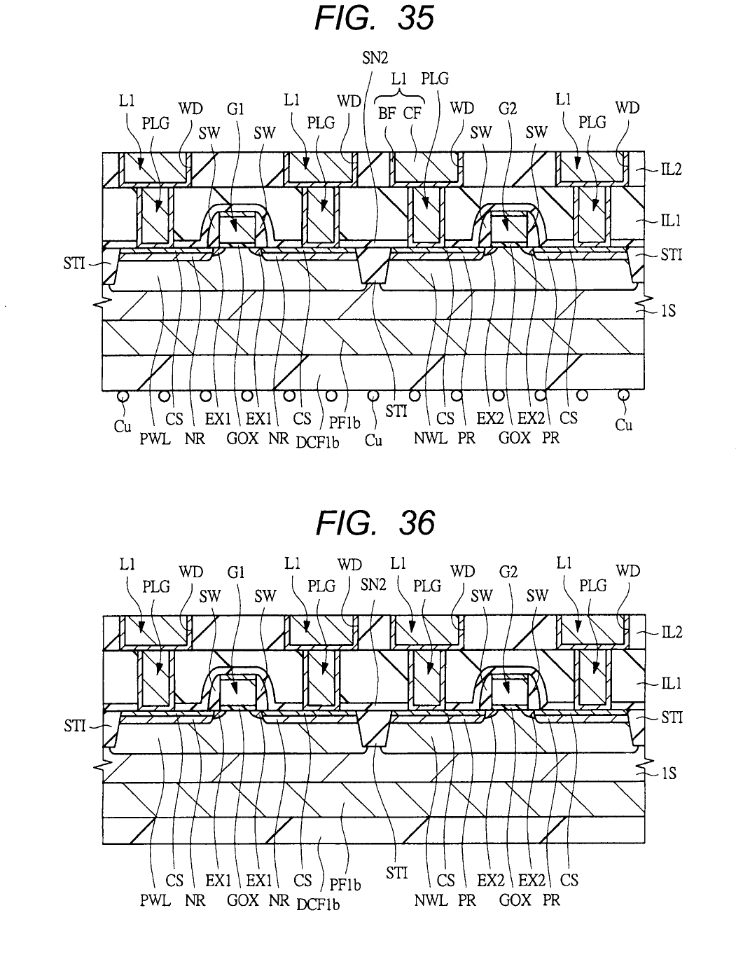

After that, as shown in FIG. 36, the semiconductor substrate 1S is subjected to a washing treatment. This can remove the copper atom Cu adhering to the surface of the copper diffusion prevention film DCF1b, for the back face of the semiconductor substrate 1S. For details, by lifting off a part of the copper diffusion prevention film DCF1b formed at the back face of the semiconductor substrate 1S, the copper atom Cu adhering to the surface of the copper diffusion prevention film DCF1b is removed effectively. That is, in the washing process, by removing a film by an amount corresponding to a very small thickness from the surface of the copper diffusion prevention film DCF1b, the copper atom Cu adhering to the surface of the copper diffusion prevention film DCF1b can be removed sufficiently. As the result, since the amount of copper atoms Cu remaining on the back face of the semiconductor substrate 1S is reduced, and the copper diffusion prevention film DCF1b inhibiting the intrusion of the copper atom Cu into the semiconductor substrate 1S has been formed, the diffusion of the copper atom Cu into the semiconductor substrate 1S can be suppressed sufficiently. Accordingly, the degradation of electric properties (such as insulation resistance) of the semiconductor element (MISFET) caused by the diffusion of the copper atom Cu can be suppressed.

After that, a multi-layer wiring is formed over the wiring L1, but the description thereof is omitted here. Here, as is the case for Embodiment 1, each of multi-layer wirings is a copper wiring, which is formed by embedding copper metal into a groove by a plating method, and, after that, removing an excessive copper metal by a CMP method to form the copper wiring in the groove. Thus, finally the semiconductor device in Embodiment 1 can be formed.

Now, inventions achieved by the present inventor are specifically explained on the basis of embodiments, but the invention is not limited to these embodiments. Needless to say, it can variously be changed within a range that does not depart from the gist thereof.

The present invention can widely be utilized for manufacturing industries that manufacture semiconductor devices.

What is claimed is:

1. A method of manufacturing a semiconductor device comprising the steps of:
(a) forming a gate insulating film over a main face of a semiconductor substrate;
(b) forming a first electroconductive film over the gate insulating film;
(c) patterning the first electroconductive film to form a gate electrode;
(d) forming a source region and a drain region in the semiconductor substrate;
(e) forming a stressor film for generating strain at a channel-forming region directly under the gate electrode, the stressor film formed over the main face of the semiconductor substrate including over the gate electrode and over a back face of the semiconductor substrate opposite the main face;
(f) removing both the stressor film formed over the main face of the semiconductor substrate including over the gate electrode and the stressor film formed over the back face of the semiconductor substrate;
(g) after the step (f), forming a first interlayer insulating film that covers the gate electrode over the main face of the semiconductor substrate;
(h) forming a plug at the first interlayer insulating film;
(i) forming a second interlayer insulating film over the first interlayer insulating film in which the plug has been formed;
(j) after the step (i), forming a copper diffusion prevention film for preventing diffusion of copper into the semiconductor substrate, the copper diffusion prevention film formed over the second interlayer insulating film formed over the main face of the semiconductor substrate and over the back face of the semiconductor substrate;
(k) after the step (j), removing the copper diffusion prevention film formed over the second interlayer insulating film;
and (l) after the step (k), forming copper wiring so as to be embedded into the second interlayer insulating film.

2. The method of manufacturing a semiconductor device according to claim 1,
wherein, in the step (l), the copper wiring is formed in a state where the copper diffusion prevention film is formed over the back face of the semiconductor substrate.

3. The method of manufacturing a semiconductor device according to claim 2,
wherein the step (l) includes the steps of:
(l1) forming a groove in the second interlayer insulating film;
(l2) forming a copper film over the second interlayer insulating film including in the groove;
and (l3) polishing the copper film to remove the copper film formed over the second interlayer insulating film and to leave the copper film in the groove, thereby forming the copper wiring in the groove.

4. The method of manufacturing a semiconductor device according to claim 3,
wherein in the step (l3), the copper film formed over the second interlayer insulating film is removed by a chemical mechanical polishing method.

5. The method of manufacturing a semiconductor device according to claim 4, further comprising the method of, after the step (l), (m) washing the semiconductor substrate.

6. The method of manufacturing a semiconductor device according to claim 5,
wherein the step (m) lifts off a part of the copper diffusion prevention film formed over the back face of the semiconductor substrate to remove a copper atom adhering to a surface of the copper diffusion prevention film.

7. The method of manufacturing a semiconductor device according to claim 1,
wherein the step (j) forms the copper diffusion prevention film both over the second interlayer insulating film formed over the main face of the semiconductor substrate and over the back face of the semiconductor substrate, using a batch-type deposition apparatus.

8. The method of manufacturing a semiconductor device according to claim 1,
wherein the step (e) forms the stressor film both over the main face of the semiconductor substrate and over the back face of the semiconductor substrate, using a batch-type deposition apparatus.

9. The method of manufacturing a semiconductor device according to claim 1,
wherein the stressor film is formed from a silicon nitride film.

10. The method of manufacturing a semiconductor device according to claim 1,
wherein the copper diffusion prevention film is formed from any of a silicon nitride film, a silicon carbonitride film, a silicon oxynitride film, and a silicon oxide film.

11. The method of manufacturing a semiconductor device according to claim 1,
wherein the first interlayer insulating film is formed from a silicon oxide film, and the second interlayer insulating film is formed from a low-permittivity film having lower permittivity than the silicon oxide film.

12. The method of manufacturing a semiconductor device according to claim 11,
wherein the second interlayer insulating film is formed from the low-permittivity film having specific permittivity of 3 or less.

13. The method of manufacturing a semiconductor device according to claim 11,
wherein the second interlayer insulating film is formed from any of an SiOC film, an MSQ film, and an HSQ film.

14. A method of manufacturing a semiconductor device comprising the steps of:
(a) forming a gate insulating film over a main face of a semiconductor substrate;
(b) forming a first electroconductive film over the gate insulating film;
(c) patterning the first electroconductive film to form a gate electrode;
(d) forming a source region and a drain region in the semiconductor substrate;
(e) forming a stressor film for generating strain at a channel-forming region directly under the gate electrode, the stressor film formed over the main face of the semiconductor substrate including over the gate electrode and over a back face of the semiconductor substrate opposite the main face;
(f) removing both the stressor film formed over the main face of the semiconductor substrate including over the gate electrode and the stressor film formed over the back face of the semiconductor substrate;
(g) after the step (f), forming a first interlayer insulating film that covers the gate electrode over the main face of the semiconductor substrate;
(h) forming a plug in the first interlayer insulating film;
(i) forming a second interlayer insulating film over the first interlayer insulating film in which the plug has been formed;
(j) after the step (i), forming a copper diffusion prevention film for preventing a diffusion of copper into the semiconductor substrate, the copper diffusion prevention film over the second interlayer insulating film formed over the main face of the semiconductor substrate and over the back face of the semiconductor substrate;
(k) after the step (j), forming a resist film over the copper diffusion prevention film formed over the second interlayer insulating film;
(l) after the step (k), patterning the resist film;
(m) after the step (l), patterning the copper diffusion prevention film formed over the second interlayer insulating film using the patterned resist film as a mask;
and (n) after the step (m), forming a groove in the second interlayer insulating film using the copper diffusion prevention film formed and patterned over the second interlayer insulating film as a mask, and forming copper wiring so as to be embedded into the groove of the second interlayer insulating film.

15. The method of manufacturing a semiconductor device according to claim 14,
wherein the step (n) includes the steps of:
(n1) forming the groove in the second interlayer insulating film using the copper diffusion prevention film formed and patterned over the second interlayer insulating film as a mask;
(n2) forming a copper film over the second interlayer insulating film including in the groove;
and (n3) polishing the copper film to remove the copper film formed over the second interlayer insulating film, and to leave the copper film in the groove, thereby forming the copper wiring in the groove.

16. The method of manufacturing a semiconductor device according to claim 15,
wherein the step (n) forms the copper wiring in a state where the copper diffusion prevention film is formed over the back face of the semiconductor substrate.

17. The method of manufacturing a semiconductor device according to claim 16, further comprising the step of after the step (n), (o) washing the semiconductor substrate.

18. The method of manufacturing a semiconductor device according to claim 17,
wherein the step (o) lifts off a part of the copper diffusion prevention film formed over the back face of the semiconductor substrate to remove a copper atom adhering to the surface of the copper diffusion prevention film.

19. The method of manufacturing a semiconductor device according to claim 14,
wherein the step (j) forms the copper diffusion prevention film both over the second interlayer insulating film formed over the main face of the semiconductor substrate and over the back face of the semiconductor substrate, using a batch-type deposition apparatus.

20. The method of manufacturing a semiconductor device according to claim 14,
wherein the step (e) forms the stressor film both over the main face of the semiconductor substrate and over the back face of the semiconductor substrate, using a batch-type deposition apparatus.

21. The method of manufacturing a semiconductor device according to claim 14,
wherein, in the step (l), the copper diffusion prevention film formed over the second interlayer insulating film functions as an antireflection film for pattering the resist film.

22. The method of manufacturing a semiconductor device according to claim 14,
wherein the stressor film is formed from a silicon nitride film.

23. The method of manufacturing a semiconductor device according to claim 14,
wherein the copper diffusion prevention film is formed from any of a silicon nitride film, a silicon carbonitride film, and a silicon oxynitride film.

24. The method of manufacturing a semiconductor device according to claim 14,
wherein the first interlayer insulating film is formed from a silicon oxide film,
and the second interlayer insulating film is formed from a low-permittivity film having lower permittivity than the silicon oxide film.

25. The method of manufacturing a semiconductor device according to claim 24,
wherein the second interlayer insulating film is formed from the low-permittivity film having specific permittivity of 3 or less.

26. The method of manufacturing a semiconductor device according to claim 24, wherein the second interlayer insulating film is formed from any of an SiOC film, an MSQ film, and an HSQ film.
